(19) United States
(12) Patent Application Publication
(10) Pub. No.: US 2026/0282363 A1
(43) Pub. Date: Sep. 17, 2026

(54) SEMICONDUCTOR DEVICE AND MANUFACTURING METHOD OF THE SEMICONDUCTOR DEVICE

(71) Applicant: SK hynix Inc., Icheon-si Gyeonggi-do (KR)

(72) Inventor: Jin Ha KIM, Icheon-si Gyeonggi-do (KR)

(73) Assignee: SK hynix Inc., Icheon-si Gyeonggi-do (KR)

(21) Appl. No.: 19/682,220

(22) Filed: May 19, 2026

Related U.S. Application Data
(63) Continuation-in-part of application No. 18/623,909, filed on Apr. 1, 2024.
Application No. 18/623,909 is a continuation of application No. 18/082,326, filed on Dec. 15, 2022, now Pat. No. 11,974,436.
Application No. 18/082,326 is a continuation of application No. 17/390,281, filed on Jul. 30, 2021, now Pat. No. 11,557,607.
Application No. 17/390,281 is a continuation of application No. 16/659,889, filed on Oct. 22, 2019, now Pat. No. 11,114,457.

(30) Foreign Application Priority Data
May 13, 2019 (KR) 10-2019-0055771

(51) Int. Cl. H10B 43/27; H10B 41/27; H10B 63/00

(52) U.S. Cl. CPC H10B 43/27; H10B 41/27; H10B 63/845

(57) ABSTRACT

A semiconductor device includes a stacked structure including conductive layers and insulating layers alternately stacked with each other in a first direction, a source layer, and a channel layer passing through the stacked structure and being in contact with the source layer. The channel layer includes a first region and a second region, and the first region is disposed between the source layer and the second region, and a first thickness of the first region is greater than a second thickness of the second region.

### CROSS-REFERENCE TO RELATED APPLICATION

The present application is a continuation-in-part of U.S. Application No. 18/623,909 filed on April 1, 2024, which is a continuation application of U.S. patent application number 18/082,326, filed on December 15, 2022 and issued as U.S. Patent No. 11,974,436 on April 30, 2024, which is a continuation application of U.S. patent application number 17/390,281, filed on July 30, 2021 and issued as U.S. Patent No. 11,557,607 on January 17, 2023, which is a continuation application of U.S. patent application number 16/659,889, filed on October 22, 2019 and issued as U.S. Patent No. 11,114,457 on September 7, 2021, which claims priority under 35 U.S.C. § 119(a) to Korean patent application number 10-2019-0055771, filed on May 13, 2019, in the Korean Intellectual Property Office, the entire contents of which applications are incorporated herein by reference.

### BACKGROUND

### 1. Technical Field

Various embodiments generally relate to an electronic device, and more particularly, to a semiconductor device and a manufacturing method of the semiconductor device.

### 2. Related Art

Non-volatile memory devices retain stored data even in the absence of a power supply. The increase in integration density of two-dimensional non-volatile memory devices in which memory cells are formed in a single layer over a substrate has recently been limited. Thus, three-dimensional non-volatile memory devices have been proposed in which memory cells are stacked in a vertical direction over a substrate.

A three-dimensional non-volatile memory device may include interlayer insulating layers and gate electrodes alternately stacked with each other and channel layers passing through the stacked structure, and memory cells may be stacked along the channel layers. Various structures and manufacturing methods have been developed to improve the operational reliability of three-dimensional non-volatile memory devices.

### SUMMARY

According to an embodiment, a semiconductor device may include a stacked structure including conductive layers and insulating layers alternately stacked with each other in a first direction, a source layer, and a channel layer passing through the stacked structure and being in contact with the source layer. The channel layer includes a first region and a second region, and the first region is disposed between the source layer and the second region, and a first thickness of the first region is greater than a second thickness of the second region.

### BRIEF DESCRIPTION OF THE DRAWINGS

FIGS. 1A and 1B are cross-sectional diagrams, illustrating the structure of a semiconductor device, according to an embodiment;

FIGS. 2A and 2B are cross-sectional diagrams, illustrating the structure of a semiconductor device, according to an embodiment;

FIGS. 3A to 3C are cross-sectional diagrams, illustrating the structure of a semiconductor device, according to an embodiment;

FIG. 4 is a cross-sectional diagram, illustrating the structure of a semiconductor device, according to an embodiment;

FIGS. 5A to 5G are cross-sectional diagrams, illustrating a method of manufacturing a semiconductor device, according to an embodiment;

FIGS. 6A and 6B are diagrams, illustrating a method of manufacturing a semiconductor device, according to an embodiment;

FIGS. 7 and 8 are block diagrams, illustrating the configuration of a memory system, according to an embodiment;

FIGS. 9 and 10 are block diagrams, illustrating the configuration of a computing system, according to an embodiment;

FIG. 11 is a diagram illustrating the structure of a semiconductor device in accordance with an embodiment;

FIG. 12 is a diagram illustrating the structure of a semiconductor device in accordance with an embodiment;

FIG. 13 is a diagram illustrating the structure of a semiconductor device in accordance with an embodiment;

FIG. 14A is a diagram illustrating the structure of a semiconductor device in accordance with an embodiment;

FIG. 14B is a diagram illustrating the structure of a semiconductor device in accordance with an embodiment;

FIG. 14C is a diagram illustrating the structure of a semiconductor device in accordance with an embodiment;

FIG. 15A is a diagram illustrating the structure of a semiconductor device in accordance with an embodiment;

FIG. 15B is a diagram illustrating the structure of a semiconductor device in accordance with an embodiment;

FIG. 15C is a diagram illustrating the structure of a semiconductor device in accordance with an embodiment;

FIG. 15D is a diagram illustrating the structure of a semiconductor device in accordance with an embodiment;

FIGS. 16A and 16B are diagrams illustrating the structure of a semiconductor device in accordance with an embodiment;

FIGS. 17A to 17D are a diagram illustrating the structure of a semiconductor device in accordance with an embodiment;

FIGS. 18A and 18B are diagrams illustrating the structure of a semiconductor device in accordance with an embodiment; and

FIGS. 19A and 19B are diagrams illustrating the structure of a semiconductor device in accordance with an embodiment.

### DETAILED DESCRIPTION

Hereinafter, various examples of embodiments will be described with reference to the accompanying drawings. In the drawings, thicknesses and distances of components may be exaggerated compared to the actual physical thicknesses and distances for convenience of illustration. In the following description, a description of known related functions and constitutions may be omitted for simplicity and conciseness. Like reference numerals refer to like elements throughout the specification and drawings.

In the drawing figures, dimensions may be exaggerated for clarity of illustration. It will be understood that when an element is referred to as being "between" two elements, it can be the only element between the two elements, or one or more intervening elements may also be present. Like reference numerals refer to like elements throughout.

It is also noted that in this specification, “connected/coupled” refers to one component not only directly connected/coupled to another component but also indirectly connected/coupled to another component through an intervening component. In the specification, when an element is referred to as “comprising” or “including” a component, it does not exclude other components but may further include other components unless a description to the contrary is specifically pointed out in context.

Various embodiments are directed to a semiconductor device with easy manufacturing processes, a stabilized structure and improved characteristics, and a manufacturing method of the semiconductor device.

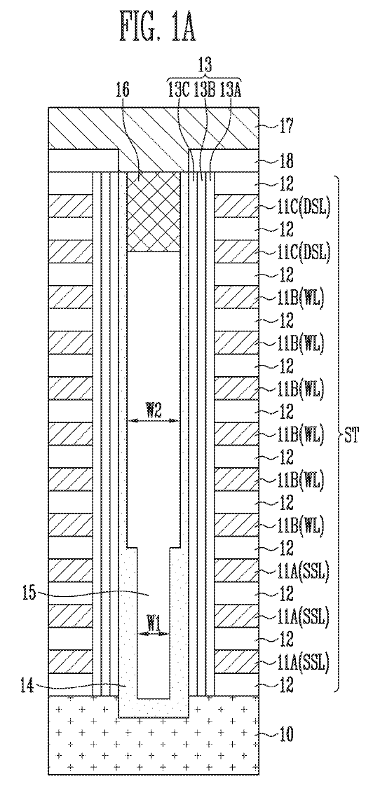

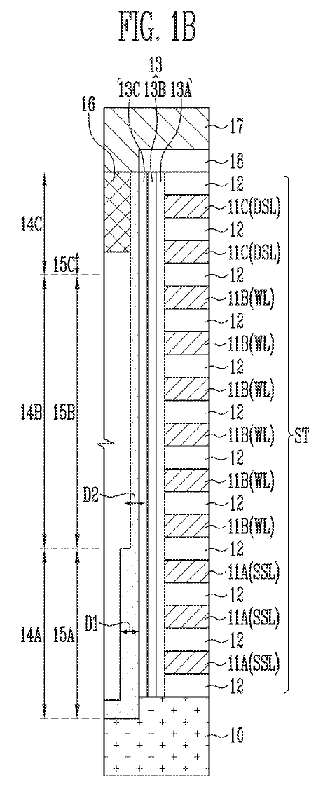

FIGS. 1A and 1B are cross-sectional diagrams, illustrating the structure of a semiconductor device, according to an embodiment.

Referring to FIG. 1A, the semiconductor device, according to an embodiment, may include a stacked structure ST, a channel structure 13, 14, 15, and 16, and a gap-fill insulating layer 15. The semiconductor device may further include at least one of a source layer 10, an interconnection structure 17, and an insulating layer 18.

The stacked structure ST may include conductive layers 11A, 11B, and 11C and insulating layers 12 alternately stacked with each other. The first and third conductive layers 11A and 11C may be select lines. The first conductive layers 11A may be source select lines SSL, and the third conductive layers 11C may be drain select lines DSL. The second conductive layers 11B may be word lines WL. The insulating layers 12 may be provided to insulate the stacked conductive layers 11A, 11B, and 11C from each other and may include an insulating material such as an oxide or a nitride.

The number of first conductive layers 11A, the number of second conductive layers 11B, and the number of third conductive layers 11C included in the stacked structure ST may vary depending on the embodiment. The number of first conductive layers 11A and the number of third conductive layers 11C may be the same or may be different. For example, the number of first conductive layers 11A may be greater than the number of third conductive layers 11C.

The channel structure 13, 14, 15, and 16 may pass through the stacked structure ST. The channel structure 13, 14, 15, and 16 may be a vertical structure and the single channel structure 13, 14, 15, and 16 may correspond to a single memory string. The channel structure 13, 14, 15, and 16 may include the channel layer 14, the memory layer 13, the gap-fill insulating layer 15 and the conductive pad 16.

The channel layer 14 may pass through the stacked structure ST in the direction in which the conductive layers 11A, 11B, and 11C and the insulating layers 12 are stacked. The channel layer 14 may be a vertical structure. The channel layer 14 may be formed in a region where a channel of a select transistor or a memory cell is formed. The channel layer 14 may include a semiconductor material such as silicon (Si) or germanium (Ge).

Select transistors may be located at intersections of the channel layer 14 and the first and third conductive layers 11A and 11C. Source select transistors may be located at intersections of the channel layer 14 and the first conductive layers 11A. Drain select transistors may be located at intersections of the channel layer 14 and the third conductive layers 11C. Memory cells may be located at intersections of the channel layer 14 and the second conductive layers 11B.

In an embodiment, the channel layer 14 may be coupled to the source layer 10. Depending on the embodiment, the bottom surface of the channel layer 14 may contact the source layer 10, the sidewall of the channel layer 14 may contact the source layer 10, or both the bottom surface and the sidewall of the channel layer 14 may contact the source layer 10. In addition, an epitaxial semiconductor layer (not shown) may be located between the channel layer 14 and the source layer 10, coupling the channel layer 14 to the source layer 10.

The gap-fill insulating layer 15 may be formed in the channel layer 14. The gap-fill insulating layer 15 may completely or partially fill the channel layer 14. When partially filled, the gap-fill insulating layer 15 may include a void. A width of the gap-fill insulating layer 15 may vary depending on the region. In addition, the gap-fill insulating layer 15 may be a single layer or a multilayer.

The memory layer 13 may be formed on the sidewall of the channel layer 14. The memory layer 13 may completely or partially surround the sidewall of the channel layer 14. The memory layer 13 may include at least one of a charge blocking layer 13A, a data storage layer 13B, and a tunnel insulating layer 13C. The data storage layer 13B may include a floating gate, a charge trapping material, polysilicon, a nitride, a variable resistance material, a phase-change material, nanodots, or the like.

The conductive pad 16 may be in contact with the channel layer 14 and may couple the channel layer 14 to the interconnection structure 17. The conductive pad 16 may also be in contact with the gap-fill insulating layer 15. The conductive pad 16 may include a conductive material such as polysilicon or tungsten.

The stacked structure ST may be located between the source layer 10 and the interconnection structure 17. The source layer 10 may include a conductive material such as polysilicon, tungsten, or metal. The source layer 10 may be a single layer or a multilayer. Alternatively, the source layer 10 may be a substrate including a source region. The interconnection structure 17 may be a bit line. The interconnection structure 17 may be formed in an insulating layer 18.

In the above-described structure, at least one source select transistor, a plurality of memory cells, and at least one drain select transistor may be coupled in series to form a single memory string. In addition, the memory string may be coupled between the source layer 10 and the bit line. The coupling of the memory string and the source layer 10 may be controlled by the source select transistor. The coupling of the memory string and the bit line may be controlled by the drain select transistor.

Select transistors and memory cells, included in a single memory string, may share the channel layer 14, and the channel layer 14 may be formed in a single layer. However, since operation performance is affected depending on the thickness of the channel layer 14, various conditions should be considered in adjusting the thickness of the channel layer 14.

An erase operation may be performed by a Gate Induced Drain Leakage (GIDL) current. The GIDL current may be generated in the source select transistor or the drain select transistor. A hole may be supplied to the channel layer 14 by using the GIDL current, and the hole may be injected into the data storage layer 13B of the memory cell by using the potential difference between the channel layer 14 and the word line WL. Accordingly, the thickness of the channel layer 14 should be great to generate a sufficient amount of GIDL current during the erase operation.

However, when the thickness of the channel layer 14 is great, swing characteristics of the transistor may deteriorate. In other words, turn-on and turn-off control of the select transistor and the memory cell may be difficult, which leads to deterioration of a cell distribution. On the contrary, when the thickness of the channel layer 14 is small, the GIDL current may decrease, and the erase operation may deteriorate. Accordingly, the reliability of the semiconductor device may suffer.

Accordingly, in an embodiment, a structure in which the single-layered channel layer 14 has the thicknesses varying, depending on a region, is proposed.

Referring to FIGS. 1A and 1B, the channel layer 14 may include a first region 14A, a second region 14B, and a third region 14C. The first region 14A may be adjacent to the source layer 10. The third region 14C may be adjacent to the interconnection structure 17, for example, the bit line. The second region 14B may be located between the first region 14A and the third region 14C. The first, second, and third regions 14A, 14B, and 14C may be coupled to form an integrated region and each of the first, second, and third regions 14A, 14B, and 14C may be a part of a single layer.

The first region 14A may correspond to the source select lines SSL, the second region 14B may correspond to the word lines WL, and the third region 14C may correspond to the drain select lines DSL. In other words, the first region 14A may be a channel region of the source select transistor, the second region 14B may be a channel region of the memory cell, and the third region 14C may be a channel region of the drain select transistor.

In an embodiment, when the erase operation is performed using the GIDL current, the GIDL current may be generated (hereinafter referred to as a GIDL region) in the first region 14A, the third region 14C, or both the first and third regions 14A and 14C. When the GIDL current is generated in both of the first and third regions 14A and 14C, the amount of GIDL current generated in both of the first and third regions 14A and 14C may differ or may be the same. The second region 14B may be a path where the hole moves.

Accordingly, the GIDL region of the channel layer 14 may selectively have a greater thickness to generate a sufficient amount of GIDL current compared to a region where the GIDL current is not generated. In addition, when the single channel layer 14 includes a plurality of GIDL regions, for example, first and third regions 14A and 14C, the thickness of the channel layer may depend on the amount of GIDL current that is generated. When the source select transistor generates a greater amount of GIDL current than the drain select transistor, the thickness D1 of the first region 14A may be greater than the thickness D2 of the second region 14B (D1>D2). The thickness D1 of the first region 14A may be greater than the thickness D2 of the third region 14C (D1>D2). The second region 14B and the third region 14C may have substantially the same thickness D2 or different thicknesses.

Each of the second and third regions 14B and 14C may have a smaller thickness than the first region 14A. Accordingly, the swing characteristics of the memory cell and/or the select transistor, corresponding to the second region 14B and/or the third region 14C, may be improved.

According to the structure as described above, the channel layer 14 may have a structure including a flat outer surface and a step-like inner surface.

A width of the gap-fill insulating layer 15 may vary according to the structure of the inner surface of the channel layer 14. The gap-fill insulating layer 15 may include a first region 15A, a second region 15B, and a third region 15C. In an embodiment, the first, second, and third regions 15A, 15B, and 15C may be coupled to form an integrated single layer. Alternatively, some of the first, second, and third regions 15A, 15B, and 15C may form different layers. However, an interface may exist between the different layers.

The first region 15A of the gap-fill insulating layer 15 may correspond to the first region 14A of the channel layer 14. Since the first region 14A has a relatively greater thickness, the first region 15A may have a relatively smaller width W1. The second region 15B of the gap-fill insulating layer 15 may correspond to the second region 14B of the channel layer 14. Since the second region 14B has a relatively smaller thickness, the second region 15B may have a relatively greater width W2. The third region 15C of the gap-fill insulating layer 15 may correspond to the third region 14C of the channel layer 14. Since the third region 14C has a relatively smaller thickness, the third region 15C may have a relatively greater width W2.

According to the structure as stated above, the single-layered channel layer 14 may be formed to have different thicknesses according to the region. The erase operation, as well as the swing characteristics of the transistor, may be improved by selectively increasing the thickness of the GIDL region of the single-layered channel layer 14.

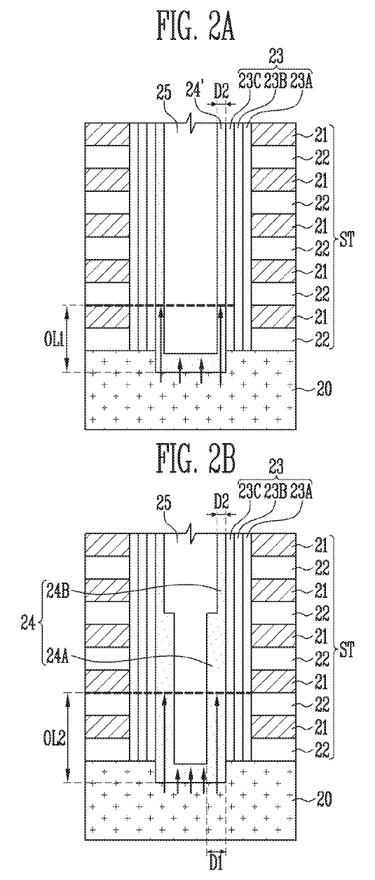

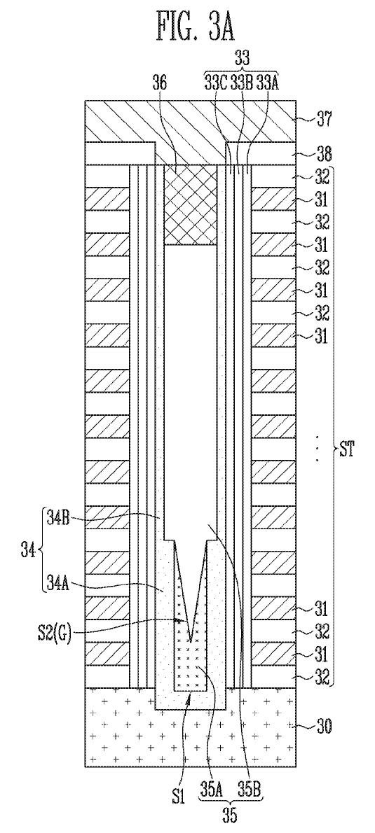

FIGS. 2A and 2B are cross-sectional diagrams, illustrating the structure of a semiconductor device, according to an embodiment and illustrate the relationship between the thickness of the channel layer 14 and the GIDL current. FIG. 2A illustrates an example in which the channel layer 24’ has a uniform and small thickness D2. FIG. 2B illustrates an example in which the first region 24A of the channel layer 24 has the greater thickness D1 than the second region 24B of the channel layer 24.

Referring to FIGS. 2A and 2B, the semiconductor device may include the stacked structure ST, a source layer 20, a memory layer 23, a channel layer 24 and 24’, a gap-fill insulating layer 25, and a conductive pad 26. The stacked structure ST may include conductive layers 21 and insulating layers 22 stacked alternately with each other. The memory layer 23 may include at least one of a charge blocking layer 23A, a data storage layer 23B, and a tunnel insulating layer 23C. The channel layer 24’ and 24 may contact the source layer 20, and a dopant in the source layer 20 may be diffused into the channel layer 24’ and 24 (please see arrows shown in FIG. 2A and FIG. 2B). A region into which the dopant is diffused may be a junction, and a first junction overlap OL1 and a second junction overlap OL2 may be shown in FIG. 2A and FIG. 2B, respectively.

The channel layer 24’, shown in FIG. 2A, may have a uniform and small thickness D2 throughout the channel layer 24’. According to this example, the swing characteristics of the select transistors and the memory cells that share the corresponding channel layer 24’ may be improved. However, since the GIDL region also has the small thickness D2, the dopant might not be sufficiently diffused. Accordingly, an area of the first junction overlap OL1 may be small and the GIDL current might not be sufficiently generated during the erase operation.

On the other hand, referring to FIG. 2B, a part of the channel layer 24 may have a greater thickness than the other part of the channel layer 24. The thickness D1 of the first region 24A may be greater than the thickness D2 of the second region 24B (D1>D2). According to this example, the dopant may be sufficiently diffused into the first region 24A where the GIDL current is generated. Accordingly, an area of the second junction overlap OL2 may be greater and the GIDL current may be sufficiently generated during the erase operation. In addition, since the memory cells of the second region 24B still have the small thickness D2 of the channel layer 24 , the swing characteristics may still be improved.

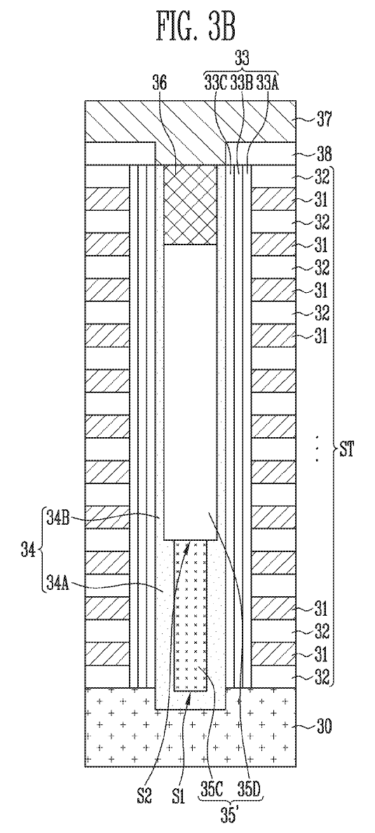

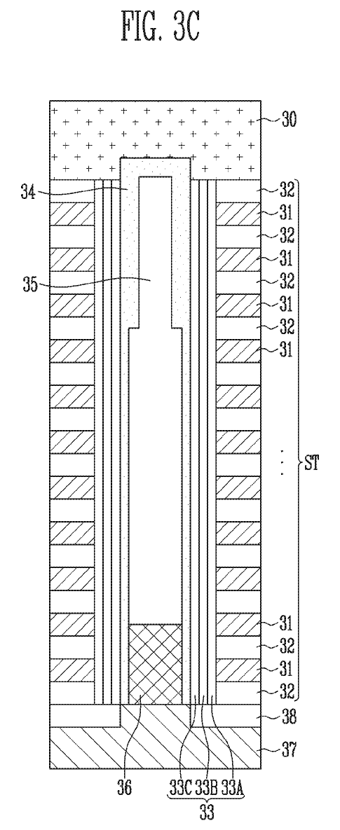

FIGS. 3A to 3C are cross-sectional diagrams, illustrating the structure of a semiconductor device, according to an embodiment. Each of FIGS. 3A, 3B, and 3C illustrates a modification of the channel structure. Hereinafter, any repetitive detailed description of components, already mentioned above, will be omitted.

Referring to FIG. 3A, the semiconductor device may include the stacked structure ST, a source layer 30, a memory layer 33, a channel layer 34, a gap-fill insulating layer 35, a conductive pad 36, a bit line 37, and an insulating layer 38. The stacked structure ST may include conductive layers 31 and insulating layers 32 alternately stacked with each other. The memory layer 33 may include at least one of a charge blocking layer 33A, a data storage layer 33B, and a tunnel insulating layer 33C.

The channel layer 34 may be a single layer including a first region 34A and a second region 34B. The thickness of the first region 34A may be greater than the thickness of the second region 34B.

The gap-fill insulating layer 35 may be formed in the channel layer 34 and may include a first gap-fill layer 35A and a second gap-fill layer 35B. The first gap-fill layer 35A may be formed in the first region 34A of the channel layer 34. The first gap-fill layer 35A may have a first surface S1 and a second surface S2. The first surface S1 may be adjacent to the source layer 30 and the second surface S2 may be adjacent to the bit line 37. In other words, the first surface S1 may be nearer to the source layer 30 than the bit line 37, and the second surface S2 may be nearer to the bit line 37 than the source layer 30. The first gap-fill layer 35A may include a groove G on the second surface S2, and the groove G may have a shape that has the width decrease, moving from the top of the first gap-fill layer 35A to the source layer 30. The second gap-fill layer 35B may be formed in the second region 34B of the channel layer 34. The second gap-fill layer 35B may include a protrusion filling the groove G of the first gap-fill layer 35A.

A material of the first gap-fill layer 35A may have etch selectivity with respect to the channel layer 34. The first gap-fill layer 35A may include an oxide, a nitride, organic matter, amorphous carbon, or the like. The channel layer 34 may be a polysilicon layer, and the first gap-fill layer 35A may be an oxide layer or a nitride layer. The second gap-fill layer 35B and the first gap-fill layer may be composed of the same material or of different materials. The second gap-fill layer 35B may include an insulating material such as an oxide.

Referring to FIG. 3B, a gap-fill insulating layer 35’ may include a first gap-fill layer 35C and a second gap-fill layer 35D. Unlike the embodiment illustrated in FIG. 3A, the second surface S2 of the first gap-fill layer 35C may be flat, according to an embodiment shown in FIG. 3B. The second gap-fill layer 35D might not include a protrusion but may have a uniform width.

Referring to FIG. 3C, the source layer 30 may be located over the bit line 37. The stacked structure ST may be located on the bit line 37, and the source layer 30 may be located on the stacked structure ST. The gap-fill insulating layer 35 may have an upper portion having a smaller width than a lower portion.

The structures described above with reference to FIGS. 1A to 1C, 2A, 2B, and 3A to 3C are examples for explanation. However, the presently claimed invention is not limited thereto. The structures described above may be combined or changed within the intent of the present disclosure.

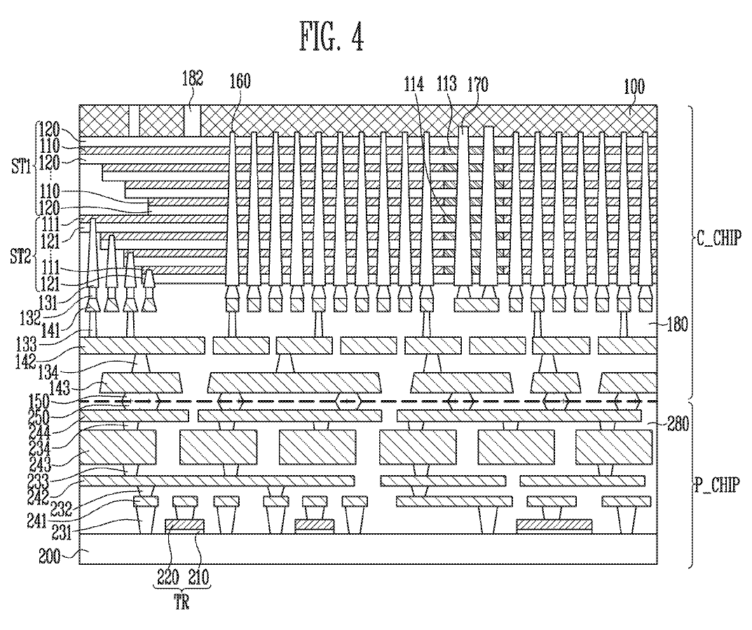

FIG. 4 is a cross-sectional diagram, illustrating the structure of a semiconductor device, according to an embodiment. Hereinafter, any repetitive detailed description of components already mentioned above will be omitted.

Referring to FIG. 4, the semiconductor device, according to an embodiment, may include a cell chip C_CHIP and a peripheral circuit chip P_CHIP, bonded to the cell chip C_CHIP. The cell chip C_CHIP may be located over the peripheral circuit chip P_CHIP or the peripheral circuit chip P_CHIP may be located over the cell chip C_CHIP.

The cell chip C_CHIP may include a source layer 100, a first stacked structure ST1, a second stacked structure ST2, an interconnection structure 131, 132, 133, 134, 141, 142, and 143, a first bonding structure 150, a channel structure 160, a source contact structure 170, and a first interlayer insulating layer 180.

The first stacked structure ST1 may include first conductive layers 110 and first insulating layers 120 alternately stacked with each other. The second stacked structure ST2 may include second conductive layers 111 and second insulating layers 121 alternately stacked with each other.

Some regions of the first stacked structure ST1 may include first sacrificial layers 113 instead of the first conductive layers 110. According to this example, the first sacrificial layers 113 and the first insulating layers 120 may be alternately stacked with each other in the regions. The second sacrificial layers 114 and the second insulating layers 121 may be alternately stacked with each other in some regions of the second stacked structure ST2. Each of the first and second sacrificial layers 113 and 114 may include a dielectric material such as a nitride.

The first stacked structure ST1 may include a cell region where memory strings are located and a contact region coupled to an interconnection structure. The second stacked structure ST2 may also include a cell region and a contact region. The contact region of each of the first and second stacked structures ST1 and ST2 may have a step-like shape.

The first stacked structure ST1 and the second stacked structure ST2 may be stacked in a vertical direction. For example, the first stacked structure ST1 may be located on the second stacked structure ST2. In addition, the cell region of the first stacked structure ST1 may overlap the cell region of the second stacked structure ST2 in a stacking direction. The contact region of the first stacked structure ST1 may overlap the contact region of the second stacked structure ST2 in the stacking direction.

The source layer 100 may be located on the first stacked structure ST1. The source layer 100 may be patterned and an insulating layer 182 may be filled between the neighboring source layers 100. The insulating layer 182 may be located to correspond to the contact region of each of the first and second stacked structures ST1 and ST2.

The channel structure 160 may pass through the first and second structures ST1 and ST2. The channel structure 160 may be coupled to the source layer 100 and may protrude into the source layer 100. The channel structure 160 may include a channel layer, a memory layer, and a gap-fill insulating layer. The channel layer and the gap-fill insulating layer may have a structure consistent with the embodiments described above with reference to FIGS. 1A to 1C, 2A, 2B, and 3A to 3C,.

The source contact structure 170 may pass through the first and second stacked structures ST1 and ST2 and may be coupled to the source layer 100. The source contact structure 170 may protrude farther into the source layer 100 than the channel structure 160. In addition, the source contact structure 170 may have a greater diameter than the channel structure 160.

The source contact structure 170 may pass through the first conductive layers 110, the first insulating layers 120, the second conductive layers 111, and the second insulating layers 121, or may pass through the first sacrificial layers 113, the first insulating layers 120, the second sacrificial layers 114, and the second insulating layers 121. The first sacrificial layers 113 may refer to the first sacrificial layers 113 which partially remain when the first sacrificial layers 113 are replaced with the first conductive layers 110. The second sacrificial layers 114 may refer to the second sacrificial layers 114 which partially remain when the second sacrificial layers 114 are replaced with the second conductive layers 111.

The source contact structure 170 may include a contact plug, and the contact plug may include a conductive material such as polysilicon, tungsten, or metal. In addition, the source contact structure 170 may further include an insulating spacer, surrounding a sidewall of the contact plug, and the insulating spacer may include an insulating material such as an oxide or a nitride.

The interconnection structure 131, 132, 133, 134, 141, 142, and 143 may include the contact plugs 131, 132, 133, and 134 and the wires 141, 142, and 143. The interconnection structure 131, 132, 133, 134, 141, 142, and 143 may be formed in the first interlayer insulating layer 180. Although FIG. 4 illustrates the first interlayer insulating layer 180 as a single layer, the first interlayer insulating layer 180 may include multiple insulating layers that are stacked.

The first contact plugs 131 may be coupled to the stacked first conductive layers 110 or the stacked second conductive layers 111 in a one-to-one manner. The second contact plugs 132 may be coupled to the first contact plugs 131, the channel structures 160, or the source contact structures 170. The second contact plugs 132 may electrically couple the first contact plugs 131 and the first wires 141. The third contact plugs 133 may be coupled to the first wires 141 and may electrically couple the first wires 141 and the second wires 142. The fourth contact plugs 134 may be coupled to the second wires 142 and may electrically couple the second wires 142 and the third wires 143.

The first bonding structure 150 may be provided to electrically couple the cell chip C_CHIP and the peripheral circuit chip P_CHIP. The first bonding structure 150 may have a shape of a contact plug, a wire, or the like. The first bonding structures 150 may be electrically coupled to the third wires 143.

The peripheral circuit chip P_CHIP may include a substrate 200, a transistor TR, an interconnection structure 231, 232, 233, 234, 241, 242, 243, and 244, a second bonding structure 250, and a second interlayer insulating layer 280.

The transistor TR may include a gate electrode 220 and a gate insulating layer 210. The gate insulating layer 210 may be interposed between the substrate 200 and the gate electrode 220. Although not illustrated in FIG. 4, the transistor TR may further include a junction in the substrate 200.

The interconnection structure 231, 232, 233, 234, 241, 242, 243 and 244 may include the contact plugs 231, 232, 233, and 234 and the wires 241, 242, 243, and 244. The interconnection structure 231, 232, 233, 234, 241, 242, 243, and 244 may be formed in the second interlayer insulating layer 280. Although FIG. 4 illustrates the second interlayer insulating layer 280 as a single layer, the second interlayer insulating layer 280 may include multiple insulating layers that are stacked.

The fifth contact plugs 231 may be coupled to the gate electrode 220 or a junction of the transistor TR. The fourth wires 241 may be electrically coupled to the fifth contact plugs 231. The sixth contact plugs 232 may electrically couple the fourth wires 241 to the fifth wires 242. The seventh contact plugs 233 may electrically couple the fifth wires 242 to the sixth wires 243. The eighth contact plugs 234 may electrically couple the sixth wires 243 to the seventh wires 244.

The second bonding structure 250 may be provided to electrically couple the cell chip C_CHIP to the peripheral circuit chip P_CHIP. The second bonding structure 250 may have a shape of a contact plug, a wire, or the like. The second bonding structures 250 may be electrically coupled to the seventh wires 244. The second bonding structures 250 may contact the first bonding structures 150 of the cell chip C_CHIP. Accordingly, the cell chip C_CHIP and the peripheral circuit chip P_CHIP may be electrically coupled through the first and second bonding structures 150 and 250. For example, the cell chip C_CHIP and the peripheral circuit chip P_CHIP may be coupled by bonding the first bonding structures 150 and the second bonding structures 250 and bonding the first interlayer insulating layer 180 and the second interlayer insulating layer 280. Accordingly, the first and second stacked structures ST1 and ST2 may be located between the substrate 200 and the source layer 100.

According to the structure as described above, after the cell chip C_CHIP and the peripheral circuit chip P_CHIP are separately manufactured, the cell chip C_CHIP and the peripheral circuit chip P_CHIP may be bonded together. In addition, the swing characteristics of the transistor as well as the erase operation may be improved by partially increasing the thickness of the channel layer included in the channel structure 160.

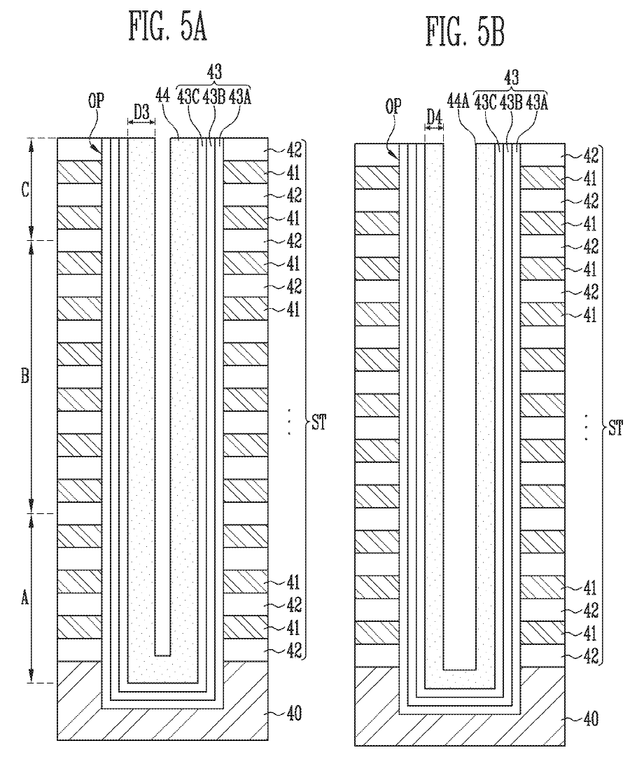

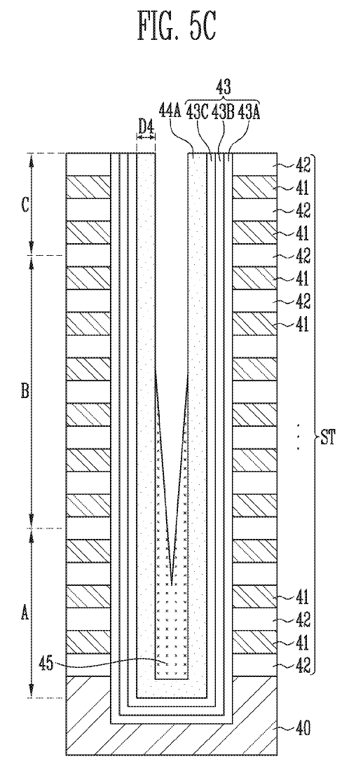

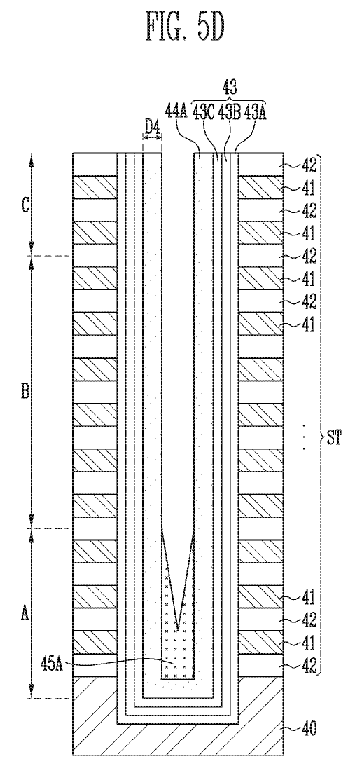

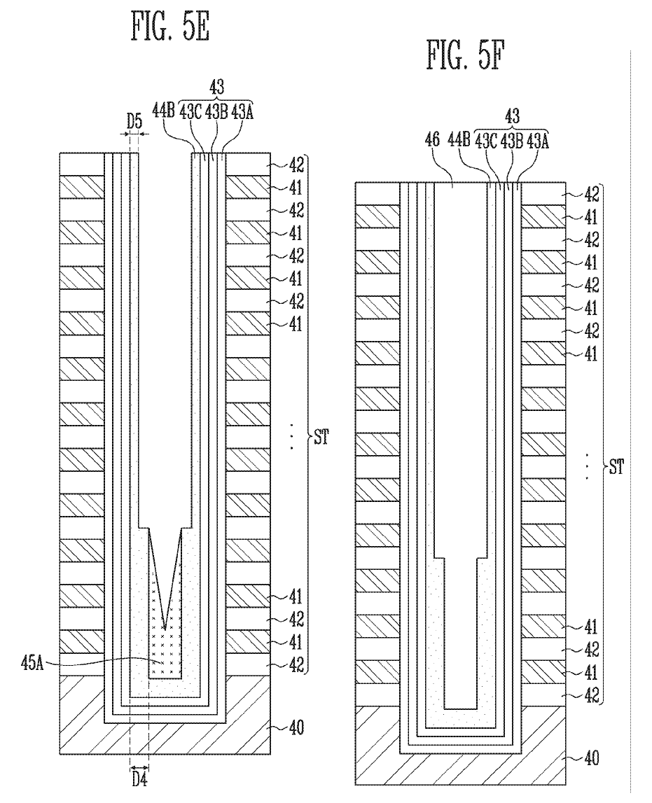

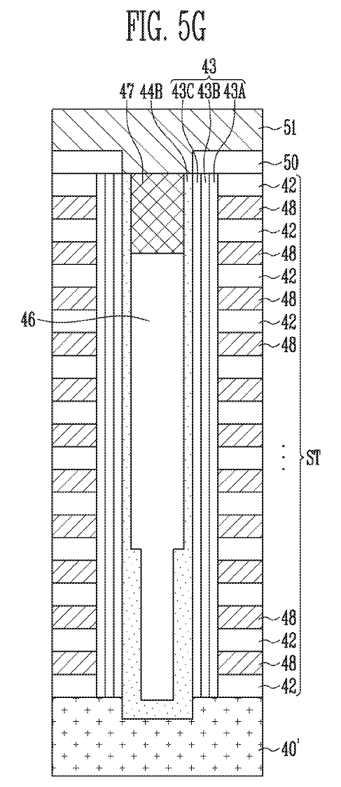

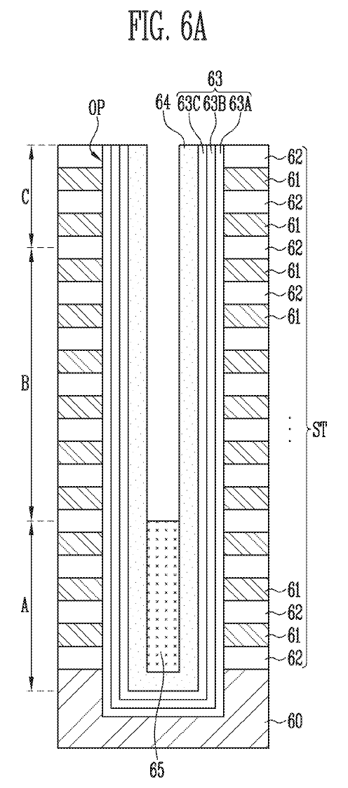

FIGS. 5A to 5G are cross-sectional diagrams, illustrating a method of manufacturing a semiconductor device, according to an embodiment. Hereinafter, any repetitive detailed description of components already mentioned above will be omitted.

Referring to FIG. 5A, the stacked structure ST may be formed on a base. The base may include a source structure, an interconnection, a peripheral circuit, and the like. The source structure may include a substrate including a source region, a source layer, a sacrificial layer for source, and the like. For example, the source structure may be a multilayer in which at least one source layer and at least one sacrificial layer are stacked. The embodiment in which the stacked structure ST is formed on a source structure 40 will be described.

The stacked structure ST may include first material layers 41 and second material layers 42 which are alternately stacked on each other. The first material layers 41 may be provided to form gate electrodes of a memory cell, a select transistor, or the like. The second material layers 42 may be provided to insulate the stacked gate electrodes from each other. The first material layers 41 may include a material having high etch selectivity with respect to the second material layers 42. In FIG. 5A, the embodiment in which the first material layers 41 are sacrificial layers and the second material layers 42 are insulating layers is illustrated. However, the presently claimed invention is not limited thereto. For example, the first material layers 41 may be sacrificial layers including a nitride, or the like, and the second material layers 42 may be insulating layers including an oxide, or the like. Alternatively, the first material layers 41 may be conductive layers including polysilicon, tungsten, or the like, and the second material layers 42 may be insulating layers including an oxide, or the like. In another example, the first material layers 41 may be conductive layers including doped polysilicon, or the like, and the second material layers 42 may be sacrificial layers including undoped polysilicon, or the like.

Subsequently, an opening OP passing through the stacked structure ST may be formed. The opening OP may expose the source structure 40 or pass through at least a portion of the source structure 40.

Subsequently, a memory layer 43 may be formed in the opening OP. The memory layer 43 may include at least one of a charge blocking layer 43A, a data storage layer 43B, and a tunnel insulating layer 43C.

Subsequently, a channel layer 44 may be formed in the opening OP. When the memory layer 43 is formed before the channel layer 44 is formed, the channel layer 44 may be formed in the memory layer 43. According to the embodiment shown in FIG. 5A, an outer surface of the channel layer 44 may be in contact with the memory layer 43. For example, the outer surface of the channel layer 44 may be in contact with the inner surface of the tunnel insulating layer 43C. The channel layer 44 may have a thickness D3 which does not completely fill the opening OP.

Although FIG. 5A illustrates the embodiment in which the memory layer 43 surrounds a sidewall and a bottom surface of the channel layer 44, the memory layer 43 may have the shape of a spacer and surround only the sidewall of the channel layer 44. For example, a surface of the source structure 40 may be exposed by etching a region, which is formed at a bottom surface of the opening OP, of the memory layer 43, using a blanket etching process. Subsequently, the channel layer 44 may be in direct contact with the source structure 40 by forming the channel layer 44 in the opening OP. In addition, the channel layer 44 may be formed after an epitaxial semiconductor grown from the exposed source structure 40 is formed.

The channel layer 44 may be a semiconductor layer including silicon (Si), germanium (Ge), or the like. For example, a polysilicon layer may be formed by forming an amorphous silicon layer and then crystallizing the amorphous silicon layer with a heat treatment process. Accordingly, the channel layer 44, including a single layer of polysilicon, may be formed.

The channel layer 44 may be a single layer including a first region A, a second region B, and a third region C. The first region A may be a GIDL region, the second region B may be a cell region, and the third region C may be a GIDL region. A range of the first region A may vary according to the number of source select lines included in the corresponding stacked structure ST. A range of the third region C may vary according to the number of drain select lines included in the corresponding stacked structure ST. A range of the second region B may vary according to the number of word lines included in the corresponding stacked structure ST.

Referring to FIG. 5B, a channel layer 44A may be etched by a primary etching. The channel layer 44A may be etched using an isotropic etching process. For example, an inner surface of the channel layer 44A may be etched using a wet etching process, such that the entire channel layer 44A may have a reduced thickness D4. The thickness of the GIDL region of the channel layer 44A may be determined by the primary etching. Accordingly, the primary etching may be omitted such that the GIDL region maintains sufficient thickness.

Referring to FIG. 5C, a sacrificial layer 45 may be formed in the opening OP. The sacrificial layer 45 may partially fill the opening OP. For example, the sacrificial layer 45 may be formed to partially fill the opening OP by being initially filled from the bottom surface of the channel layer 44A.

The sacrificial layer 45 may be formed by a bottom-up filling method in which the opening OP is filled from the bottom surface thereof. For example, a deposition process for depositing a sacrificial material and a surface treatment process for suppressing deposition at an upper surface of the opening OP may be repeatedly performed. The deposition process may be performed by an Atomic Layer Deposition (ALD) method. The surface treatment process may be performed using plasma. Nucleation at the upper surface of the opening OP may be suppressed by plasma. Accordingly, the sacrificial layer 45 covering the first region A of the channel layer 44A and exposing the second and third regions B and C of the channel layer 44A may be formed. Alternatively, the sacrificial layer 45, covering the first region A of the channel layer 44A with a thick layer and covering the second and third regions B and C of the channel layer 44A with a thin layer, may be formed.

When the sacrificial layer 45 may be formed at the second region B or the third region C, a process for exposing the second region B and the third region C may be further performed. Referring to FIG. 5D, a sacrificial layer 45A may be etched to expose the second region B and the third region C. For example, the sacrificial layer 45A may be selectively etched using a wet etching process. Accordingly, the sacrificial layer 45A covering the first region A of the channel layer 44A and exposing the second region B and the third region C of the channel layer 44A may be formed. Referring to FIG. 5E, a channel layer 44B may be etched by a secondary etching using the sacrificial layer 45A as an etching barrier. For example, the channel layer 44B may be etched to decrease a thickness of the channel layer 44B. The channel layer 44B may be etched using an isotropic etching process. The channel layer 44B may be etched using a wet etching process. The second region B and the third region C exposed by the sacrificial layer 45A may be etched and the first region A might not be etched. Accordingly, the first region A may have the thickness D4 and each of the second region B and the third region C may have a thickness D5 smaller than the thickness D4.

Referring to FIG. 5F, a gap-fill insulating layer 46 may be formed in the opening OP. The sacrificial layer 45A may be removed before the gap-fill insulating layer 46 is formed. When the sacrificial layer 45A is not removed, the remaining sacrificial layer 45A may serve as a gap-fill layer.

Referring to FIG. 5G, after the gap-fill insulating layer 46 is etched, a conductive pad 47 may be formed in a region from which the gap-fill insulating layer 46 is etched. Subsequently, the first material layers 41 or the second material layers 42 may be replaced by third material layers 48. For example, when the first material layers 41 are sacrificial layers and the second material layers 42 are insulating layers, the first material layers 41 may be replaced by conductive layers. Alternatively, when the first material layers 41 are conductive layers and the second material layers 42 are insulating layers, the first material layers 41 may be silicidized. As a further alternative, when the first material layers 41 are conductive layers and the second material layers 42 are sacrificial layers, the second material layers 42 may be replaced by insulating layers.

In addition, depending on the material of the source structure 40, an additional process to directly couple the source structure 40 to the channel layer 44B may be performed. The additional process may be performed before or after replacing the first material layers 41 or the second material layers 42 by the third material layers 48. First, an opening, exposing the memory layer 43, may be formed by removing the sacrificial layer included in the source structure 40. Subsequently, the channel layer 44B may be exposed in the opening by removing the exposed memory layer 43. Then, a source layer may be formed in the opening. Accordingly, the sacrificial layer in the source structure 40 may be replaced by the source layer and a source structure 40’ directly coupled to the channel layer 44B may be formed.

Subsequently, an interconnection structure, coupled to the channel layer 44B, may be formed. For example, a bit line 51, coupled to the channel layer 44B, may be formed over the stacked structure ST. The bit line 51 may be formed in an interlayer insulating layer 50.

The manufacturing method, described above, with reference to FIGS. 5A to 5G, may be applied when the cell chip C_CHIP, described above, with reference to FIG. 4, is manufactured. Accordingly, the peripheral circuit chip P_CHIP, manufactured by a separate process, may be formed, and a process for bonding the cell chip C_CHIP and the peripheral circuit chip P_CHIP may be additionally performed.

According to the manufacturing method as described above, the channel layer 44B may be formed to have a single-layered structure having different thicknesses depending on the region. For example, the thicknesses of the channel layer 44B may be readily adjusted by the region and by selectively etching some regions of the channel layer 44B by using the sacrificial layer 45A.

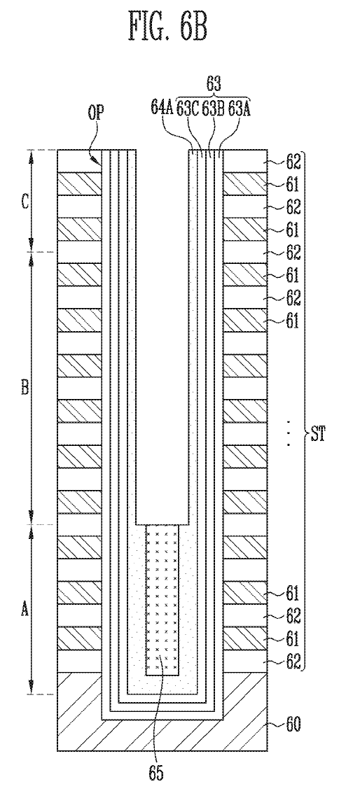

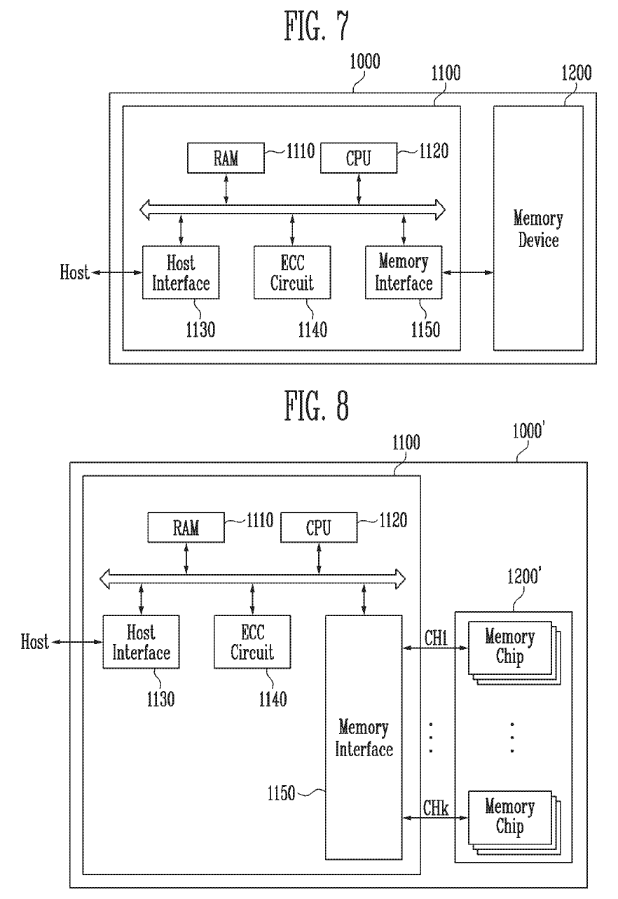

FIGS. 6A and 6B are diagrams, illustrating a method of manufacturing a semiconductor device, according to an embodiment. Hereinafter, any repetitive detailed description of components already mentioned above will be omitted.

Referring to FIG. 6A, the stacked structure ST may be formed on a source structure 60. The stacked structure ST may include first material layers 61 and second material layers 62, which are alternately stacked with each other. Subsequently, after the opening OP passing through the stacked structure ST is formed, a memory layer 63 may be formed in the opening OP. The memory layer 63 may include a charge blocking layer 63A, a data storage layer 63B, and a tunnel insulating layer 63C. Subsequently, a channel layer 64 may be formed in the memory layer 63.

Subsequently, a sacrificial layer 65 may be formed in the channel layer 64. The sacrificial layer 65 may fill the channel layer 64 from the bottom surface thereof to the top portion of the first region A. For example, a flowable material may be formed in the opening OP. Subsequently, the sacrificial layer 65 may be formed by densifying the flowable material by a heat treatment process. The flowable material may be an oxide, a Spin On Glass (SOG) material, or the like. Due to the characteristics of the flowable material, the flowable material may fill a lower portion of the opening OP and have a structure having a flat upper surface.

Referring to FIG. 6B, a channel layer 64A may be etched using the sacrificial layer 65 as an etching barrier. The second region B and the third region C exposed by the sacrificial layer 65 may be etched by a predetermined thickness and the first region A covered by the sacrificial layer 65 might not be etched. A subsequent process such as forming a gap-fill insulating layer may be performed.

According to the process described above, the sacrificial layer 65 may be formed by using the flowable material and filling the opening OP from the bottom surface thereof. Accordingly, the sacrificial layer 65 having a desired height may be easily formed.

FIG. 7 is a block diagram, illustrating the configuration of a memory system 1000, according to an embodiment.

Referring FIG. 7, the memory system 1000, according to an embodiment, may include a memory device 1200 and a controller 1100.

The memory device 1200 may be used to store data information having various data formats such as a text format, a graphical format, and a software code format. The memory device 1200 may be a non-volatile memory device. Furthermore, the memory device 1200 may have a structure consistent with the embodiments described above with reference to FIGS. 1A to 6B, and may be manufactured by a manufacturing method consistent with the embodiments described above with reference to FIGS. 1A to 6B. According to an embodiment, the memory device 1200 may include a stacked structure including conductive layers and insulating layers alternately stacked with each other, a channel layer passing through the stacked structure, and a gap-fill insulating layer in the channel layer. The channel layer may be a single layer including a first GIDL region, a cell region, and a second GIDL region. The first GIDL region may have a greater thickness than each of the cell region and the second GIDL region. Since the memory device 1200 is configured and manufactured in the same manner as described above, a detailed description thereof will be omitted.

The controller 1100 may be coupled to a host and the memory device 1200 and configured to access the memory device 1200 in response to a request from the host. For example, the controller 1100 may control read, write, erase, and background operations of the memory device 1200.

The controller 1100 may include Random Access Memory (RAM) 1110, a Central Processing Unit (CPU) 1120, a host interface 1130, an Error Correction Code (ECC) circuit 1140, a memory interface 1150, and the like.

The RAM 1110 may be used as an operation memory of the CPU 1120, a cache memory between the memory device 1200 and the host, a buffer memory between the memory device 1200 and the host, or the like. The RAM 1110 may be replaced with Static Random Access Memory (SRAM), Read Only Memory (ROM), or the like.

The CPU 1120 may control the overall operation of the controller 1100. For example, the CPU 1120 may operate firmware such as a Flash Translation Layer (FTL) stored in the RAM 1110.

The host interface 1130 may interface with the host. For example, the controller 1100 may communicate with the host through at least one of various interface protocols such as a Universal Serial Bus (USB) protocol, a MultiMedia Card (MMC) protocol, a Peripheral Component Interconnection (PCI) protocol, a PCI-Express (PCI-E) protocol, an Advanced Technology Attachment (ATA) protocol, a Serial-ATA protocol, a Parallel-ATA protocol, a Small Computer Small Interface (SCSI) protocol, an Enhanced Small Disk Interface (ESDI) protocol, and an Integrated Drive Electronics (IDE) protocol, a private protocol, and the like.

The ECC circuit 1140 may use an Error Correction Code (ECC) to detect and correct errors in data read from the memory device 1200.

The memory interface 1150 may interface with the memory device 1200. For example, the memory interface 1150 may include a NAND interface or a NOR interface.

The controller 1100 may further include a buffer memory (not shown) for temporarily storing data. The buffer memory may be used to temporarily store data to be transferred to an external device through the host interface 1130 or data to be transferred from the memory device 1200 through the memory interface 1150. The controller 1100 may further include ROM which stores code data to interface with the host.

Since the memory system 1000 according to the embodiment includes the memory device 1200 having improved integration density and characteristics, the memory system 1000 may also have improved integration density and characteristics accordingly.

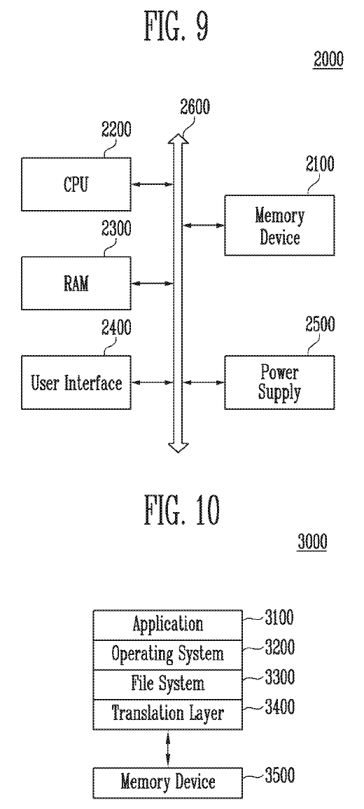

FIG. 8 is a block diagram, illustrating the configuration of a memory system 1000’, according to an embodiment. Hereinafter, any repetitive detailed description of components already mentioned above will be omitted.

Referring to FIG. 8, the memory system 1000’, according to an embodiment, may include a memory device 1200’ and the controller 1100. The controller 1100 may include the RAM 1110, the CPU 1120, the host interface 1130, the ECC circuit 1140, the memory interface 1150, and the like.

The memory device 1200’ may be a non-volatile memory device. Furthermore, the memory device 1200’ may have a structure consistent with the embodiments described above with reference to FIGS. 1A to 6B, and may be manufactured by a manufacturing method consistent with the embodiments described above with reference to FIGS. 1A to 6B. According to an embodiment, the memory device 1200’ may include a stacked structure including conductive layers and insulating layers alternately stacked with each other, a channel layer passing through the stacked structure, and a gap-fill insulating layer in the channel layer. The channel layer may be a single layer including a first GIDL region, a cell region, and a second GIDL region. The first GIDL region may have a greater thickness than each of the cell region and the second GIDL region. Since the memory device 1200’ is configured and manufactured in the same manner as described above, a detailed description thereof will be omitted.

Furthermore, the memory device 1200’ may be a multi-chip package including a plurality of memory chips. The plurality of memory chips may be divided into a plurality of groups which may communicate with the controller 1100 through first to kth channels CH1 to CHk. In addition, memory chips, included in a single group, may be suitable for communicating with the controller 1100 through a common channel. The memory system 1000’ may be modified so that a single memory chip may be coupled to a single channel.

Since the memory system 1000’ according to the embodiment includes the memory device 1200’ having improved integration density and characteristics, the integration density and characteristics of the memory system 1000’ may also be improved. In addition, since the memory device 1200’ is formed into a multi-chip package, data storage capacity and driving speed of the memory system 1000’ may be further increased.

FIG. 9 is a block diagram, showing the configuration of a computing system 2000, according to an embodiment. Hereinafter, any repetitive detailed description of components already mentioned above will be omitted.

Referring to FIG. 9, the computing system 2000, according to an embodiment, may include a memory device 2100, a CPU 2200, RAM 2300, a user interface 2400, a power supply 2500, a system bus 2600, and the like.

The memory device 2100 may store data provided via the user interface 2400, data processed by the CPU 2200, and the like. The memory device 2100 may be electrically coupled to the CPU 2200, the RAM 2300, the user interface 2400, and the power supply 2500 by the system bus 2600. For example, the memory device 2100 may be coupled to the system bus 2600 via a controller (not shown), alternatively, directly coupled to the system bus 2600. When the memory device 2100 is directly coupled to the system bus 2600, functions of the controller may be performed by the CPU 2200, the RAM 2300, or the like.

The memory device 2100 may be a non-volatile memory. Furthermore, the memory device 2100 may have a structure consistent with the embodiments described above with reference to FIGS. 1A to 6B, and may be manufactured by a manufacturing method consistent with the embodiments described above with reference to FIGS. 1A to 6B. According to an embodiment, the memory device 2100 may include a stacked structure including conductive layers and insulating layers alternately stacked with each other, a channel layer passing through the stacked structure, and a gap-fill insulating layer in the channel layer. The channel layer may be a single layer including a first GIDL region, a cell region, and a second GIDL region. The first GIDL region may have a greater thickness than each of the cell region and the second GIDL region. Since the memory device 2100 is configured and manufactured in the same manner as described above, a detailed description thereof will be omitted.

As described above with reference to FIG. 8, the memory device 2100 may be a multi-chip package configured with a plurality of memory chips.

The computing system 2000 having the above-described configuration may be provided as one of various elements of an electronic device such as a computer, an Ultra Mobile PC (UMPC), a workstation, a net-book, a Personal Digital Assistant (PDA), a portable computer, a web tablet, a wireless phone, a mobile phone, a smartphone, an e-book, a Portable Multimedia Player (PMP), a game console, a navigation device, a black box, a digital camera, a 3-dimensional television, a digital audio recorder, a digital audio player, a digital picture recorder, a digital picture player, a digital video recorder, a digital video player, a device capable of transmitting/receiving information in an wireless environment, one of various electronic devices for forming a home network, one of various electronic devices for forming a computer network, one of various electronic devices for forming a telematics network, an RFID device, or the like.

As described above, since the computing system 2000 according to the embodiment includes the memory device 2100 having improved integration density and characteristics, the characteristics of the computing system 2000 may also be improved.

FIG. 10 is a block diagram, illustrating a computing system 3000, according to an embodiment.

Referring to FIG. 10, the computing system 3000, according to an embodiment, may include a software layer that has an operating system 3200, an application 3100, a file system 3300, and a translation layer 3400. Furthermore, the computing system 3000 may include a hardware layer such as a memory device 3500.

The operating system 3200 may manage software and hardware resources of the computing system 3000. The operating system 3200 may control program execution of a central processing unit. The application 3100 may include various application programs executed by the computing system 3000. The application 3100 may be a utility executed by the operating system 3200.

The file system 3300 may refer to a logical structure configured to manage data and files present in the computing system 3000. The file system 3300 may organize files or data to be stored in the memory device 3500 according to given rules. The file system 3300 may be determined depending on the operating system 3200 used in the computing system 3000. For example, when the operating system 3200 is a Microsoft Windows-based system, the file system 3300 may be a File Allocation Table (FAT), an NT file system (NTFS), or the like. In addition, when the operating system 3200 is a Unix/Linux-based system, the file system 3300 may be an extended file system (EXT), a Unix File System (UFS), a Journaling File System (JFS), or the like.

FIG. 10 illustrates the operating system 3200, the application 3100, and the file system 3300 in separate blocks. However, the application 3100 and the file system 3300 may be included in the operating system 3200.

The translation layer 3400 may translate an address into a suitable form for the memory device 3500 in response to a request from the file system 3300. For example, the translation layer 3400 may translate a logical address, generated by the file system 3300, into a physical address of the memory device 3500. Mapping information of the logical address and the physical address may be stored in an address translation table. For example, the translation layer 3400 may be a Flash Translation Layer (FTL), a Universal Flash Storage Link Layer (ULL), or the like.

The memory device 3500 may be a non-volatile memory. Furthermore, the memory device 3500 may have a structure consistent with the embodiments described above with reference to FIGS. 1A to 6B, and may be manufactured by a manufacturing method consistent with the embodiments described above with reference to FIGS. 1A to 6B. According to an embodiment, the memory device 3500 may include a stacked structure including conductive layers and insulating layers alternately stacked with each other, a channel layer passing through the stacked structure, and a gap-fill insulating layer in the channel layer. The channel layer may be a single layer including a first GIDL region, a cell region, and a second GIDL region. The first GIDL region may have a greater thickness than each of the cell region and the second GIDL region. Since the memory device 3500 is configured and manufactured in the same manner as described above, a detailed description thereof will be omitted.

The computing system 3000 having the above-described configuration may be divided into an operating system layer that is operated in an upper level region and a controller layer that is operated in a lower level region. The application 3100, the operating system 3200, and the file system 3300 may be included in the operating system layer, and may be driven by an operating memory of the computing system 3000. The translation layer 3400 may be included in the operating system layer or the controller layer.

As described above, since the computing system 3000 according to the embodiment includes the memory device 3500 having improved integration density and characteristics, the characteristics of the computing system 3000 may also be improved.

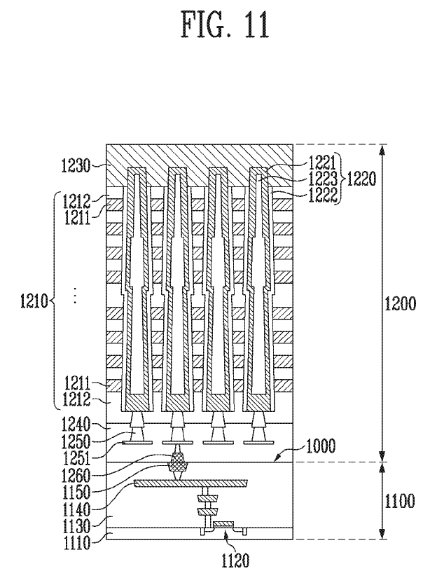

FIG. 11 is a diagram illustrating the structure of a semiconductor device in accordance with an embodiment.

Referring to FIG. 11, the semiconductor device may include a first semiconductor structure 1100 and a second semiconductor structure 1200. The first semiconductor structure 1100 of FIG. 11 may correspond to the peripheral circuit chip P_CHIP of FIG. 4. The peripheral circuit chip may be referred to as the peripheral circuit structure. The second semiconductor structure 1200 of FIG. 11 may correspond to the cell chip C_CHIP of FIG. 4. A bonding interface 1000 may be located in the semiconductor device, and the first semiconductor structure 1100 is distinguished from the second semiconductor structure 1200 by the bonding interface 1000. The second semiconductor structure 1200 may be disposed over or under the first semiconductor structure 1100. The first semiconductor structure 1100 may include a peripheral circuit, and the second semiconductor structure 1200 may include a memory cell array.

The first semiconductor structure 1100 may include a substrate 1110 (e.g., the substrate 200 of FIG. 4), a transistor 1120 (e.g., the transistor TR of FIG. 4), a first interlayer insulating layer 1130 (e.g., the second interlayer insulating layer 280 of FIG. 4), a first interconnection structure 1140 (e.g., the interconnection structure 231, 232, 233, 234, 241, 242, 243, and 244 of FIG. 4), and a first bonding pad 1150 (e.g., the second bonding structures 250 of FIG. 4). The transistor 1120 may be included in the peripheral circuit. The peripheral circuit may include a row decoder, a page buffer, an input/output circuit, a logic circuit, and the like. The first interconnection structure 1140 may be disposed in the first interlayer insulating layer 1130 and may include a via, a wiring line, and the like. The first bonding pad 1150 may be disposed at the bonding interface 1000 and may be electrically connected to the peripheral circuit through the first interconnection structure 1140.

The second semiconductor structure 1200 may include a gate structure 1210 (e.g., the first and second stacked structures ST1 and ST2 of FIG. 4), a channel structure 1220 (e.g., the channel structure 160 of FIG. 4), a source structure 1230 (e.g., the source layer 100 of FIG. 4), a second interlayer insulating layer 1240 (e.g., the first interlayer insulating layer 180 of FIG. 4), a second interconnection structure 1250 (e.g., the interconnection structure 131, 132, 133, 134, 141, 142, and 143 of FIG. 4), and a second bonding pad 1260 (e.g., the first bonding structure 150 of FIG. 4). The gate structure 1210 may include gate lines 1211 (e.g., the first conductive layers 110 and the second conductive layers 111 of FIG. 4) alternately stacked with insulating layers 1212 (e.g., the first insulating layers 120 and the second insulating layers 121 of FIG. 4). The source structure 1230 may be disposed over the gate structure 1210. The channel structure 1220 may include a channel layer 1221 (e.g., the channel layer 14 of FIG. 1A), a memory layer 1222 (e.g., the memory layer 13 of FIG. 1A), and/or an insulating core 1223 (e.g., the gap-fill insulating layer 15 of FIG. 1A). The channel layer 1221 may extend through the gate structure 1210 and may be connected to the source structure 1230. The second interconnection structure 1250 may be disposed in the second interlayer insulating layer 1240 and may include a via, a wiring line, and the like. For example, the second interconnection structure 1250 may include a bit line 1251. The second bonding pad 1260 may be disposed at the bonding interface 1000 and may be electrically connected to the memory cell array through the second interconnection structure 1250.

A thickness of a portion of the channel layer 1221 may be greater than a thickness of another portion of the channel layer 1221. Referring to FIGS. 1B and 11, the channel layer 1221 may include the first region 14A, the second region 14B, and the third region 14C. The thickness D1 of the first region 14A may be greater than the thickness D2 of the second region 14B. Each of the second and third regions 14B and 14C may have a smaller thickness than the first region 14A. Referring to FIGS. 4 and 11, the channel layer 1221 may have an uneven profile (e.g., a recess or a protrusion) between the first and second stacked structures ST1 and ST2. The channel layer 1221 may have a step-like outer surface and the step-like inner surface. For example, openings may be formed in the first stacked structure ST1, and sacrificial pillars may be formed in the openings. After the second stacked structure ST2 is formed, openings may be formed in the second stacked structure ST2 to expose the sacrificial pillars, and the sacrificial pillars may be removed. Subsequently, processes described with reference to FIGS. 5A to 5G and FIGS. 6A to 6B may be performed.

The first bonding pad 1150 may be electrically connected to the second bonding pad 1260 at the bonding interface 1000, and the memory cell array may be electrically connected to the peripheral circuit through the first bonding pad 1150 and the second bonding pad 1260.

The semiconductor device may be manufactured using a method such as hybrid bonding, metal bonding, insulator bonding, or semiconductor bonding. For example, the semiconductor device may be manufactured by manufacturing a first wafer including the peripheral circuit and a second wafer including the memory cell array, and bonding the first wafer to the second wafer.

Some of the first semiconductor structure 1100 and the second semiconductor structure 1200 may be formed after the first wafer is bonded to the second wafer. For example, the second wafer including a substrate, the gate structure 1210, and the channel structure 1220 may be formed, flipped, and bonded to the first wafer including the transistor 1120. Subsequently, a rear surface of the gate structure 1210 may be exposed by removing the substrate of the second wafer, and the channel layer 1221 may be exposed by etching the memory layer 1222 of the channel structure 1220 protruding from the rear surface of the gate structure 1210. The source structure 1230 may be formed on the rear surface of the gate structure 1210.

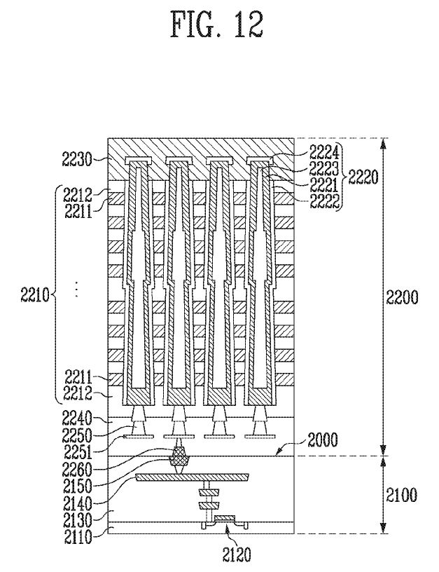

FIG. 12 is a diagram illustrating the structure of a semiconductor device in accordance with an embodiment.

Referring to FIG. 12, the semiconductor device may include a first semiconductor structure 2100 and a second semiconductor structure 2200. The first semiconductor structure 2100 of FIG. 12 may correspond to the peripheral circuit chip P_CHIP of FIG. 4. The second semiconductor structure 2200 of FIG. 12 may correspond to the cell chip C_CHIP of FIG. 4. A bonding interface 2000 may be located in the semiconductor device, and the first semiconductor structure 2100 may be distinguished from the second semiconductor structure 2200 by the bonding interface 2000. The second semiconductor structure 2200 may be disposed over or under the first semiconductor structure 2100. The first semiconductor structure 2100 may include a peripheral circuit, and the second semiconductor structure 2200 may include a memory cell array.

The first semiconductor structure 2100 may include a substrate 2110 (e.g., the substrate 200 of FIG. 4), a transistor 2120 (e.g., the transistor TR of FIG. 4), a first interlayer insulating layer 2130 (e.g., the second interlayer insulating layer 280 of FIG. 4), a first interconnection structure 2140 (e.g., the interconnection structure 231, 232, 233, 234, 241, 242, 243, and 244 of FIG. 4), and a first bonding pad 2150 (e.g., the second bonding structures 250 of FIG. 4). The transistor 2120 may be included in the peripheral circuit. The peripheral circuit may include a row decoder, a page buffer, an input/output circuit, a logic circuit, and the like. The first interconnection structure 2140 may be disposed in the first interlayer insulating layer 2130 and may include a via, a wiring line, and the like. The first bonding pad 2150 may be disposed at the bonding interface 2000 and may be electrically connected to the peripheral circuit through the first interconnection structure 2140.

The second semiconductor structure 2200 may include a gate structure 2210 (e.g., the first and second stacked structures ST1 and ST2 of FIG. 4), a channel structure 2220 (e.g., the channel structure 160 of FIG. 4), a source structure 2230 (e.g., the source layer 100 of FIG. 4), a second interlayer insulating layer 2240 (e.g., the first interlayer insulating layer 180 of FIG. 4), a second interconnection structure 2250 (e.g., the interconnection structure 131, 132, 133, 134, 141, 142, and 143 of FIG. 4), and a second bonding pad 2260 (e.g., the first bonding structure 150 of FIG. 4). The gate structure 2210 may include gate lines 2211 (e.g., the first conductive layers 110 and the second conductive layers 111 of FIG. 4) alternately stacked with insulating layers 2212 (e.g., the first insulating layers 120 and the second insulating layers 121 of FIG. 4). The source structure 2230 may be disposed over the gate structure 2210. The channel structure 2220 may include a channel layer 2221 (e.g., the channel layer 14 of FIG. 1A), a memory layer 2222 (e.g., the memory layer 13 of FIG. 1A), an insulating core 2223 (e.g., the gap-fill insulating layer 15 of FIG. 1A), and/or a memory pattern 2224. The channel layer 2221 may extend through the gate structure 2210 and may be connected to the source structure 2230 (e.g., the source layer 10 of FIG. 1A). The second interconnection structure 2250 may be disposed in the second interlayer insulating layer 2240 and may include a via, a wiring line, and the like. For example, the second interconnection structure 2250 may include a bit line 2251. The second bonding pad 2260 may be disposed at the bonding interface 2000 and may be electrically connected to the memory cell array through the second interconnection structure 2250.

A thickness of a portion of the channel layer 2221 may be greater than a thickness of another portion of the channel layer 2221. Referring to FIGS. 1B and 12, the channel layer 2221 may include the first region 14A, the second region 14B, and the third region 14C. The thickness D1 of the first region 14A may be greater than the thickness D2 of the second region 14B. Each of the second and third regions 14B and 14C may have a smaller thickness than the first region 14A. The first region 14A, the second region 14B, and the third region 14C may be formed as a continuous layer. The first region 14A, the second region 14B, and the third region 14C may be integral layer. The first region 14A, the second region 14B, and the third region 14C may be integrally formed. Referring to FIGS. 4 and 12, the channel layer 2221 may have an uneven profile (e.g., a recess or a protrusion) between the first and second stacked structures ST1 and ST2. The channel layer 2221 may have a step-like outer surface and the step-like inner surface. Referring to FIGS. 5A to 5G and 12, the source structure 40 may include a first source layer, a source sacrificial layer, and a second source layer. The source sacrificial layer may be disposed between the first source layer and the second source layer. The opening OP may penetrate the stacked structure ST (e.g., the gate structure 2210), the second source layer, and the source sacrificial layer. After the channel structure 2220 is formed in the opening OP, the source sacrificial layer and a portion of the memory layer 43 may be removed to expose the channel layer 2221. A third source layer may be formed between the first source layer and the second source layer and may be in contact with the channel layer 2221. Another portion of the memory layer 43 disposed in the first source layer may remain as the memory pattern 2224.

The first bonding pad 2150 may be electrically connected to the second bonding pad 2260 at the bonding interface 2000, and the memory cell array may be electrically connected to the peripheral circuit through the first bonding pad 2150 and the second bonding pad 2260.

The semiconductor device may be manufactured using a method such as hybrid bonding, metal bonding, insulator bonding, or semiconductor bonding. For example, the semiconductor device may be manufactured by manufacturing a first wafer including the peripheral circuit and a second wafer including the memory cell array, and bonding the first wafer to the second wafer.

When the second wafer is manufactured, the source structure 2230 may be connected to the channel layer 2221 using a source sacrificial layer. For example, the channel structure 2220 may be formed to protrude into a source structure including the source sacrificial layer. An opening exposing the channel structure 2220 may be formed by removing the source sacrificial layer, and the channel layer 2221 may be exposed by etching the memory layer 2222 through the opening. A source layer connected to the channel layer 2221 may be formed in the opening to form the source structure 2230 including the source layer. The second wafer including the source structure 2230 may be flipped and bonded to the first wafer including the transistor 2120.

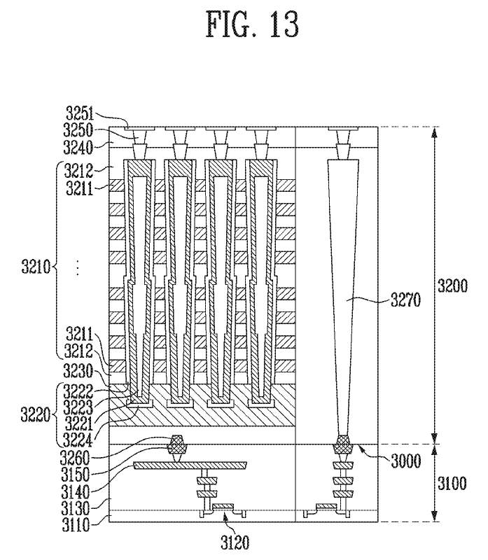

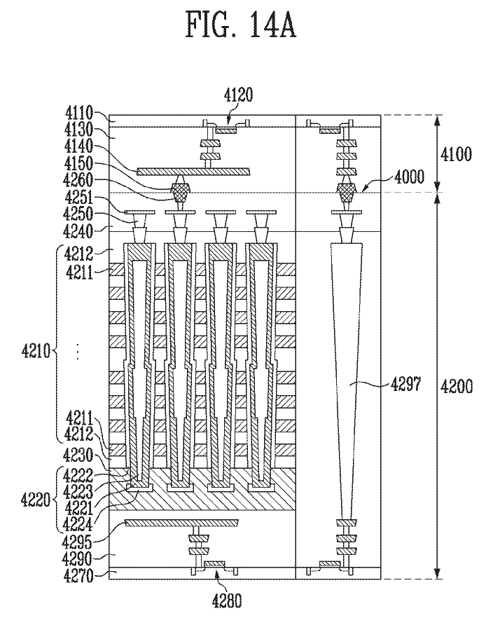

FIG. 13 is a diagram illustrating the structure of a semiconductor device in accordance with an embodiment.

Referring to FIG. 13, the semiconductor device may include a first semiconductor structure 3100 and a second semiconductor structure 3200. A bonding interface 3000 may be located in the semiconductor device, and the first semiconductor structure 3100 may be distinguished from the second semiconductor structure 3200 by the bonding interface 3000. The second semiconductor structure 3200 may be disposed over or under the first semiconductor structure 3100. The first semiconductor structure 3100 may include a peripheral circuit, and the second semiconductor structure 3200 may include a memory cell array.

The first semiconductor structure 3100 may include a substrate 3110 (e.g., the substrate 200 of FIG. 4), a transistor 3120 (e.g., the transistor TR of FIG. 4), a first interlayer insulating layer 3130 (e.g., the second interlayer insulating layer 280 of FIG. 4), a first interconnection structure 3140 (e.g., the interconnection structure 231, 232, 233, 234, 241, 242, 243, and 244 of FIG. 4), and a first bonding pad 3150 (e.g., the second bonding structures 250 of FIG. 4). The transistor 3120 may be included in the peripheral circuit. The peripheral circuit may include a row decoder, a page buffer, an input/output circuit, a logic circuit, and the like. The first interconnection structure 3140 may be disposed in the first interlayer insulating layer 3130 and may include a via, a wiring line, and the like. The first bonding pad 3150 may be disposed at the bonding interface 3000 and may be electrically connected to the peripheral circuit through the first interconnection structure 3140.

The second semiconductor structure 3200 may include a gate structure 3210 (e.g., the first and second stacked structures ST1 and ST2 of FIG. 4), a channel structure 3220 (e.g., the channel structure 160 of FIG. 4), a source structure 3230 (e.g., the source layer 100 of FIG. 4), a second interlayer insulating layer 3240 (e.g., the first interlayer insulating layer 180 of FIG. 4), a second interconnection structure 3250 (e.g., the interconnection structure 131, 132, 133, 134, 141, 142, and 143 of FIG. 4), a second bonding pad 3260 (e.g., the first bonding structure 150 of FIG. 4), and a contact plug 3270. The gate structure 3210 may include gate lines 3211 (e.g., the first conductive layers 110 and the second conductive layers 111 of FIG. 4) alternately stacked with insulating layers 3212 (e.g., the first insulating layers 120 and the second insulating layers 121 of FIG. 4). The source structure 3230 (e.g., the source layer 10 of FIG. 1A) may be disposed below the gate structure 3210. The channel structure 3220 may include a channel layer 3221 (e.g., the channel layer 14 of FIG. 1A), a memory layer 3222 (e.g., the memory layer 13 of FIG. 1A), an insulating core 3223 (e.g., the gap-fill insulating layer 15 of FIG. 1A), and/or a memory pattern 3224. The channel layer 3221 may extend through the gate structure 3210, and may be connected to the source structure 3230. The second interconnection structure 3250 may be disposed in the second interlayer insulating layer 3240 and may include a via, a wiring line, and the like. For example, the second interconnection structure 3250 may include a bit line 3251. The second bonding pad 3260 may be disposed at the bonding interface 3000 and may be electrically connected to the memory cell array through the second interconnection structure 3250.

The first bonding pad 3150 may be electrically connected to the second bonding pad 3260 at the bonding interface 3000, and the memory cell array may be electrically connected to the peripheral circuit through the first bonding pad 3150 and the second bonding pad 3260. The contact plug 3270 may extend through the second interlayer insulating layer 3240 or a dummy stack and may be connected to the peripheral circuit through the first bonding pad 3150 and the second bonding pad 3260.

The semiconductor device may be manufactured using a method such as hybrid bonding, metal bonding, insulator bonding, or semiconductor bonding. For example, the semiconductor device may be manufactured by manufacturing a first wafer including the peripheral circuit and a second wafer including the memory cell array, and bonding the first wafer to the second wafer.

When the second wafer is manufactured, the source structure 3230 may be connected to the channel layer 3221 using a source sacrificial layer. For example, the channel structure 3220 protrudes into a source structure including the source sacrificial layer. Subsequently, an opening exposing the channel structure 3220 may be formed by removing the source sacrificial layer, and the channel layer 3221 may be exposed by etching the memory layer 3222 through the opening. A source layer connected to the channel layer 3221 may be formed in the opening to form the source structure 3230 including the source layer. The second wafer including the source structure 3230 may be bonded to the first wafer including the transistor 3120. In this example, the second wafer may be bonded to the first wafer in an un-flipped state. An interconnection structure such as a through silicon via (TSV) may be formed.

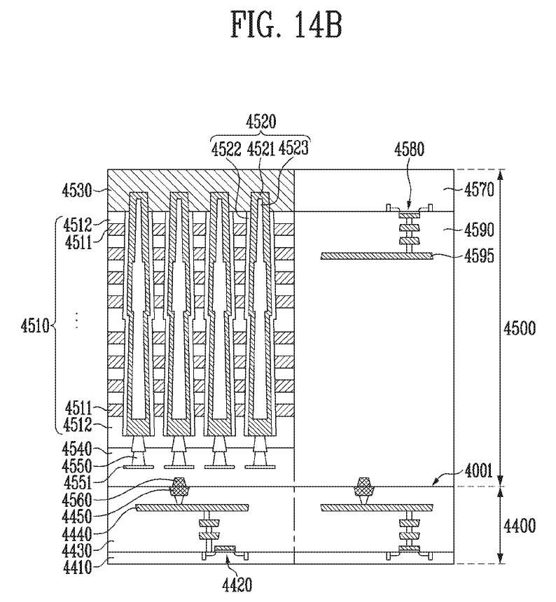

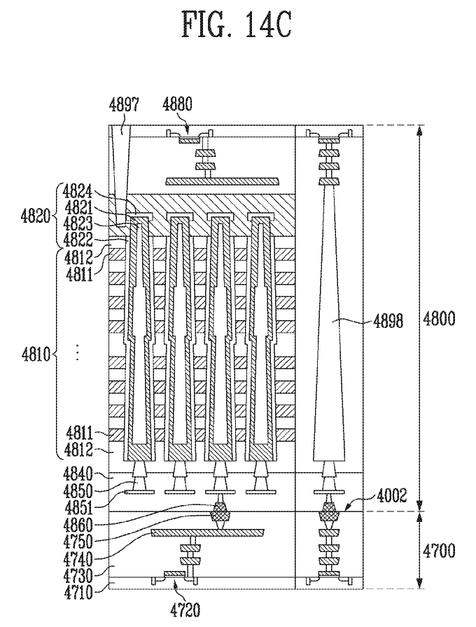

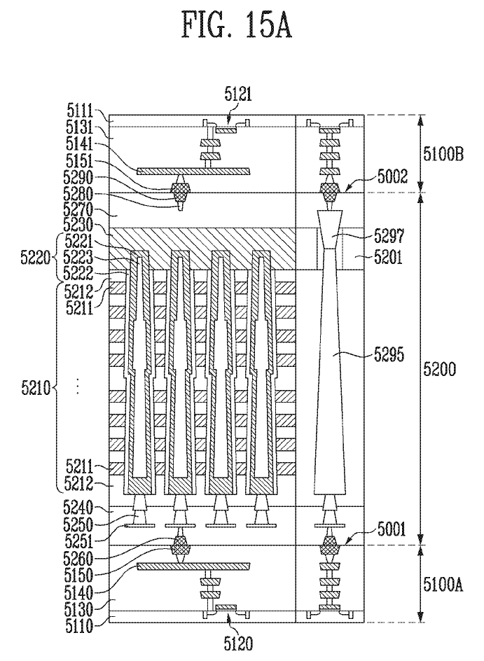

FIG. 14A is a diagram illustrating the structure of a semiconductor device in accordance with an embodiment.

Referring to FIG. 14A, the semiconductor device may include a first semiconductor structure 4100 and a second semiconductor structure 4200. A bonding interface 4000 may be located in the semiconductor device, and the first semiconductor structure 4100 may be distinguished from the second semiconductor structure 4200 by the bonding interface 4000. The second semiconductor structure 4200 may be disposed over or under the first semiconductor structure 4100. A peripheral circuit may include a first peripheral circuit and a second peripheral circuit. The first peripheral circuit and the second peripheral circuit may be distributed and disposed in the first semiconductor structure 4100 and the second semiconductor structure 4200. The first semiconductor structure 4100 may include the first peripheral circuit, and the second semiconductor structure 4200 may include the second peripheral circuit and a memory cell array.

The first semiconductor structure 4100 may include a first substrate 4110, a first transistor 4120, a first interlayer insulating layer 4130, a first interconnection structure 4140, and a first bonding pad 4150. The first transistor 4120 may be included in the first peripheral circuit. The first peripheral circuit may include a row decoder, a page buffer, an input/output circuit, a logic circuit, and the like. The first interconnection structure 4140 may be disposed in the first interlayer insulating layer 4130 and may include a via, a wiring line, and the like. The first bonding pad 4150 may be disposed at the bonding interface 4000 and may be electrically connected to the first peripheral circuit through the first interconnection structure 4140.

The second semiconductor structure 4200 may include a gate structure 4210, a channel structure 4220, a source structure 4230, a second interlayer insulating layer 4240, a second interconnection structure 4250, a second bonding pad 4260, a second substrate 4270, a second transistor 4280, a third interlayer insulating layer 4290, a third interconnection structure 4295, and a contact plug 4297.

The second transistor 4280 may be disposed on the second substrate 4270. The second transistor 4280 may be included in the second peripheral circuit. The second peripheral circuit may include a row decoder, a page buffer, an input/output circuit, a logic circuit, and the like. The third interconnection structure 4295 may be formed in the third interlayer insulating layer 4290 and may include a via, a wiring line, and the like. The third interconnection structure 4295 may be electrically connected to the second peripheral circuit.

The gate structure 4210 may be disposed over the second peripheral circuit. The gate structure 4210 may include gate lines 4211 alternately stacked with insulating layers 4212. The source structure 4230 may be disposed under the gate structure 4210. The channel structure 4220 may include a channel layer 4221, a memory layer 4222, an insulating core 4223, and/or a memory pattern 4224. The channel layer 4221 may extend through the gate structure 4210 and may be connected to the source structure 4230. The second interconnection structure 4250 may be disposed in the second interlayer insulating layer 4240 and may include a via, a wiring line, and the like. For example, the second interconnection structure 4250 may include a bit line 4251. The second bonding pad 4260 may be disposed at the bonding interface 4000 and may be electrically connected to the memory cell array through the second interconnection structure 4250.

The first bonding pad 4150 may be electrically connected to the second bonding pad 4260 at the bonding interface 4000, and the memory cell array may be electrically connected to the first peripheral circuit through the first bonding pad 4150 and the second bonding pad 4260. The contact plug 4297 may extend through the second interlayer insulating layer 4240 or a dummy stack. The first peripheral circuit may be connected to the second peripheral circuit through the contact plug 4297, the first bonding pad 4150 and the second bonding pad 4260.

The semiconductor device may be manufactured using a method such as hybrid bonding, metal bonding, insulator bonding, or semiconductor bonding. For example, the semiconductor device may be manufactured by manufacturing a first wafer including the first peripheral circuit and a second wafer including the second peripheral circuit and the memory cell array, and bonding the first wafer to the second wafer.

When the second wafer is manufactured, the source structure 4230 may be connected to the channel layer 4221 using a source sacrificial layer. For example, the second peripheral circuit may be formed on the second substrate 4270, and a source structure including the source sacrificial layer and the channel structure 4220 protruding into the source structure may be formed over the second peripheral circuit. An opening exposing the channel structure 4220 may be formed by removing the source sacrificial layer, and the channel layer 4221 may be exposed by etching the memory layer 4222 through the opening. A source layer connected to the channel layer 4221 may be formed in the opening to form the source structure 4230 including the source layer. The second wafer including the second peripheral circuit and the source structure 4230 may be bonded to the first wafer including the first peripheral circuit.

FIG. 14B is a diagram illustrating the structure of a semiconductor device in accordance with an embodiment.

Referring to FIG. 14B, the semiconductor device may include a first semiconductor structure 4400 and a second semiconductor structure 4500. A bonding interface 4001 may be located in the semiconductor device, and the first semiconductor structure 4400 may be distinguished from the second semiconductor structure 4500 by the bonding interface 4001. The second semiconductor structure 4500 may be disposed over or under the first semiconductor structure 4400. A peripheral circuit may include a first peripheral circuit and a second peripheral circuit. The first peripheral circuit and the second peripheral circuit may be distributed and disposed in the first semiconductor structure 4400 and the second semiconductor structure 4500. The first semiconductor structure 4400 may include the first peripheral circuit, and the second semiconductor structure 4500 may include the second peripheral circuit and a memory cell array.

The first semiconductor structure 4400 may include a first substrate 4410, a first transistor 4420, a first interlayer insulating layer 4430, a first interconnection structure 4440, and a first bonding pad 4450. The first transistor 4420 may be included in the first peripheral circuit. The first peripheral circuit may include a row decoder, a page buffer, an input/output circuit, a logic circuit, and the like. The first interconnection structure 4440 may be disposed in the first interlayer insulating layer 4430 and may include a via, a wiring line, and the like. The first interconnection structure 4440 may be electrically connected to the first peripheral circuit.

The second semiconductor structure 4500 may include a gate structure 4510, a channel structure 4520, a source structure 4530, a second interlayer insulating layer 4540, a second interconnection structure 4550, a second bonding pad 4560, a second substrate 4570, a second transistor 4580, a third interlayer insulating layer 4590, and a third interconnection structure 4595.

The second transistor 4580 may be disposed on the second substrate 4570. The second transistor 4580 may be included in the second peripheral circuit. The third interconnection structure 4595 may be formed in the third interlayer insulating layer 4590 and may include a via, a wiring line, and the like. The third interconnection structure 4595 may be electrically connected to the second peripheral circuit.

The source structure 4530 may be disposed at a level corresponding to the second substrate 4570, and the gate structure 4510 may be disposed under the source structure 4530. The gate structure 4510 may include gate lines 4511 alternately stacked with insulating layers 4512. The channel structure 4520 may include a channel layer 4521, a memory layer 4522, and/or an insulating core 4523. The channel layer 4521 may extend through the gate structure 4510 and may be connected to the source structure 4530. The second interconnection structure 4550 may be disposed in the second interlayer insulating layer 4540 and may include a via, a wiring line, and the like. For example, the second interconnection structure 4550 may include a bit line 4551. The second bonding pad 4560 may be disposed at the bonding interface 4001, and may be electrically connected to the memory cell array through the second interconnection structure 4550.

The first bonding pad 4450 may be electrically connected to the second bonding pad 4560 at the bonding interface 4001, and the memory cell array may be electrically connected to the first peripheral circuit through the first bonding pad 4450 and the second bonding pad 4560.

The semiconductor device may be manufactured using a method such as hybrid bonding, metal bonding, insulator bonding, or semiconductor bonding. For example, the semiconductor device may be manufactured by manufacturing a first wafer including the first peripheral circuit and a second wafer including the second peripheral circuit and the memory cell array, and bonding the first wafer to the second wafer.

Some of the first semiconductor structure 4400 and the second semiconductor structure 4500 may be formed after the first wafer is bonded to the second wafer. For example, the second peripheral circuit may be formed in a peripheral region of the second substrate 4560, and the channel structure 4520 protruding into the second substrate 4570 may be formed in a cell region of the second substrate 4570. The second wafer including the second peripheral circuit and the source structure 4530 may be flipped and bonded to the first wafer including the first peripheral circuit. Subsequently, a rear surface of the gate structure 4510 may be exposed by removing the cell region of the second substrate 4570, and the channel layer 4521 may be exposed by etching the memory layer 4522 of the channel structure 4520 protruding from the rear surface of the gate structure 4510. The source structure 4530 may be formed on the rear surface of the gate structure 4510.

FIG. 14C is a diagram illustrating the structure of a semiconductor device in accordance with an embodiment.

Referring to FIG. 14C, the semiconductor device may include a first semiconductor structure 4700 and a second semiconductor structure 4800. A bonding interface 4002 may be located in the semiconductor device, and the first semiconductor structure 4700 may be distinguished from the second semiconductor structure 4800 by the bonding interface 4002. The second semiconductor structure 4800 may be disposed over or under the first semiconductor structure 4700. A peripheral circuit may include a first peripheral circuit and a second peripheral circuit. The first peripheral circuit and the second peripheral circuit may be distributed and disposed in the first semiconductor structure 4700 and the second semiconductor structure 4800. The first semiconductor structure 4700 may include the first peripheral circuit, and the second semiconductor structure 4800 may include the second peripheral circuit and a memory cell array.

The first semiconductor structure 4700 may include a first substrate 4710, a first transistor 4720, a first interlayer insulating layer 4730, a first interconnection structure 4740, and a first bonding pad 4750. The first transistor 4720 may be included in the first peripheral circuit. The first peripheral circuit may include a row decoder, a page buffer, an input/output circuit, a logic circuit, and the like. The first interconnection structure 4740 may be disposed in the first interlayer insulating layer 4730 and may include a via, a wiring line, and the like. The first bonding pad 4750 may be disposed at the bonding interface 4002 and may be electrically connected to the first peripheral circuit through the first interconnection structure 4740.

The second semiconductor structure 4800 may include a gate structure 4810, a channel structure 4820, a source structure 4830, a second interlayer insulating layer 4840, a second interconnection structure 4850, a second bonding pad 4860, a second substrate 4870, a second transistor 4880, a third interlayer insulating layer 4890, a third interconnection structure 4895, a through via 4897, and a contact plug 4898.

The second transistor 4880 may be disposed on the second substrate 4870. The second transistor 4880 may be included in the second peripheral circuit. The second peripheral circuit may include a row decoder, a page buffer, an input/output circuit, a logic circuit, and the like. The third interconnection structure 4895 may be formed in the third interlayer insulating layer 4890 and may include a via, a wiring line, and the like. The third interconnection structure 4895 may be electrically connected to the second peripheral circuit.

The source structure 4830 may be disposed under the second peripheral circuit. The through via 4897 may extend through the second substrate 4870 and the third interlayer insulating layer 4890 and may be connected to the source structure 4830. The gate structure 4810 may be disposed under the source structure 4830. The gate structure 4810 may include gate lines 4811 alternately stacked with insulating layers 4812. The channel structure 4820 may include a channel layer 4821, a memory layer 4822, an insulating core 4823, and/or a memory pattern 4824. The channel layer 4821 may extend through the gate structure 4810 and may be connected to the source structure 4830. The second interconnection structure 4850 may be disposed in the second interlayer insulating layer 4840 and may include a via, a wiring line, and the like. For example, the second interconnection structure 4850 may include a bit line 4851. The second bonding pad 4860 may be disposed at the bonding interface 4002 and may be electrically connected to the memory cell array through the second interconnection structure 4850.

The first bonding pad 4750 may be electrically connected to the second bonding pad 4860 at the bonding interface 4002, and the memory cell array may be electrically connected to the first peripheral circuit through the first bonding pad 4750 and the second bonding pad 4860. The contact plug 4898 may extend through the second interlayer insulating layer 4840 or a dummy stack. The first peripheral circuit may be connected to the second peripheral circuit through the contact plug 4898, the first bonding pad 4750 and the second bonding pad 4860.

The semiconductor device may be manufactured using a method such as hybrid bonding, metal bonding, insulator bonding, or semiconductor bonding. For example, the semiconductor device may be manufactured by manufacturing a first wafer including the first peripheral circuit and a second wafer including the second peripheral circuit and the memory cell array, and bonding the first wafer to the second wafer.

Some of the first semiconductor structure 4700 and the second semiconductor structure 4800 may be formed after the first wafer may be bonded to the second wafer. For example, the second wafer including the second substrate 4870, the second peripheral circuit, and a source structure including a source sacrificial layer may be formed. The second wafer may be flipped and bonded to the first wafer including the first peripheral circuit. Subsequently, a through hole extending through the second substrate 4870 and the third interlayer insulating layer 4890 to expose the source sacrificial layer may be formed, and an opening, through which the channel structure 4820 is exposed, may be formed by removing the source sacrificial layer through the through hole. The channel layer 4821 may be exposed by etching the memory layer 4822 through the opening, and a source layer connected to the channel layer 4821 may be formed in the opening to form the source structure 4830 including the source layer. The through via 4897 may be formed in the through hole.

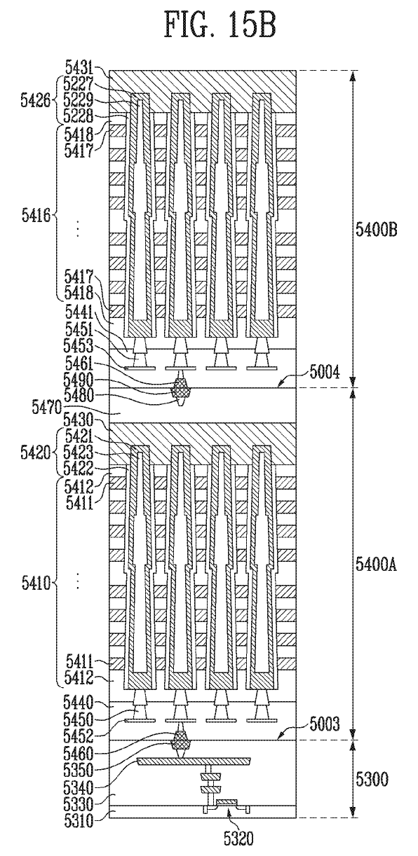

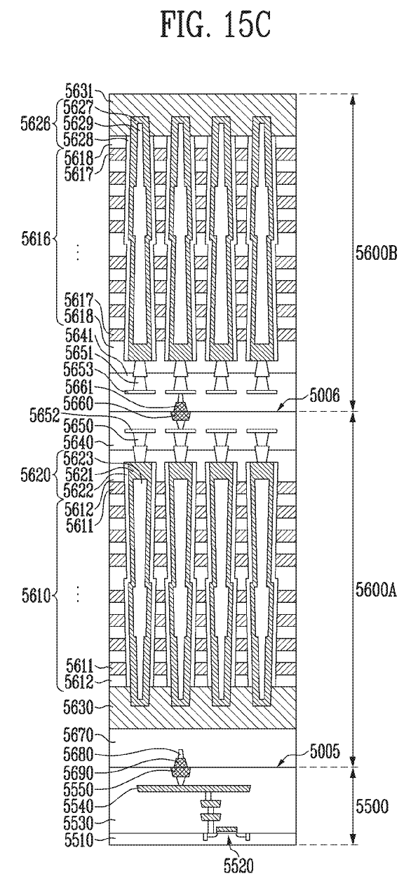

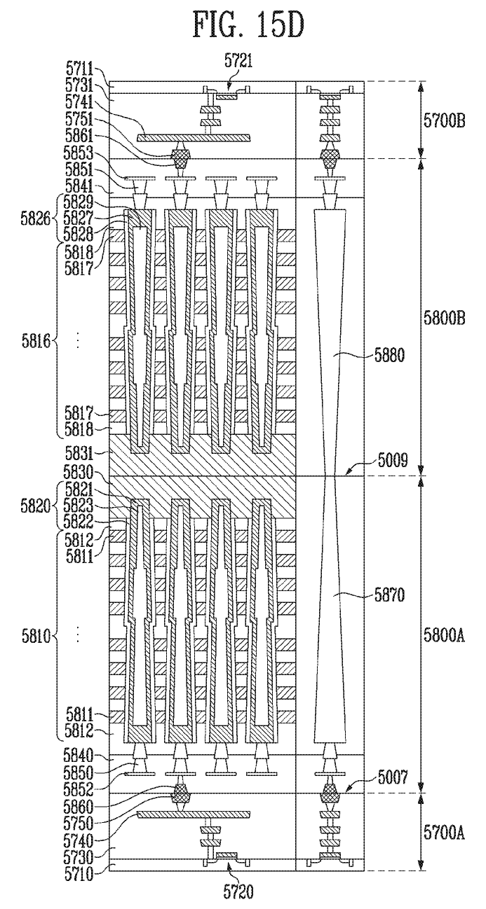

FIG. 15A is a diagram illustrating the structure of a semiconductor device in accordance with an embodiment.

Referring to FIG. 15A, the semiconductor device may include a first semiconductor structure 5100A, a second semiconductor structure 5100B, and a third semiconductor structure 5200. Bonding interfaces 5001 and 5002 may be located in the semiconductor device, and the first semiconductor structure 5100A, the second semiconductor structure 5100B, and the third semiconductor structure 5200 may be distinguished from each other by the bonding interfaces 5001 and 5002. The third semiconductor structure 5200 may be disposed between the first semiconductor structure 5100A and the second semiconductor structure 5100B. A peripheral circuit may include a first peripheral circuit and a second peripheral circuit. The first peripheral circuit and the second peripheral circuit may be distributed and disposed in the first semiconductor structure 5100A and the second semiconductor structure 5100B. The first semiconductor structure 5100A may include the first peripheral circuit, the second semiconductor structure 5100B may include the second peripheral circuit, and the third semiconductor structure 5200 may include a memory cell array.

The first semiconductor structure 5100A may include a first substrate 5110, a first transistor 5120, a first interlayer insulating layer 5130, a first interconnection structure 5140, and a first bonding pad 5150. The first transistor 5120 may be included in the first peripheral circuit. The first peripheral circuit may include a row decoder, a page buffer, an input/output circuit, a logic circuit, and the like. The first interconnection structure 5140 may be disposed in the first interlayer insulating layer 5130 and may include a via, a wiring line, and the like. The first bonding pad 5150 may be disposed at a first bonding interface 5001 and may be electrically connected to the first peripheral circuit through the first interconnection structure 5140.

The second semiconductor structure 5100B may include a second substrate 5111, a second transistor 5121, a second interlayer insulating layer 5131, a second interconnection structure 5141, and a second bonding pad 5151. The second transistor 5121 may be included in the second peripheral circuit. The second peripheral circuit may include a row decoder, a page buffer, an input/output circuit, a logic circuit, and the like. The second interconnection structure 5141 may be disposed in the second interlayer insulating layer 5131 and may include a via, a wiring line, and the like. The second bonding pad 5151 may be disposed at a second bonding interface 5002 and may be electrically connected to the second peripheral circuit through the second interconnection structure 5141.

The third semiconductor structure 5200 may include a substrate 5201, a gate structure 5210, a channel structure 5220, a source structure 5230, a third interlayer insulating layer 5240, a third interconnection structure 5250, a third bonding pad 5260, a fourth interlayer insulating layer 5270, a fourth interconnection structure 5280, a fourth bonding pad 5290, a first contact plug 5295, and a second contact plug 5297. The gate structure 5210 may include gate lines 5211 alternately stacked with insulating layers 5212. The source structure 5230 may be disposed over or under the gate structure 5210. The channel structure 5220 may include a channel layer 5221, a memory layer 5222, and/or an insulating core 5223. The channel layer 5221 may extend through the gate structure 5210 and may be connected to the source structure 5230. The third interconnection structure 5250 may be disposed in the third interlayer insulating layer 5240 and may include a via, a wiring line, and the like. For example, the third interconnection structure 5250 may include a bit line 5251. The fourth interconnection structure 5280 may be disposed in the fourth interlayer insulating layer 5270 and may include a via, a wiring line, and the like. The third bonding pad 5260 may be disposed at the first bonding interface 5001 and may be electrically connected to the memory cell array through the third interconnection structure 5250. The fourth bonding pad 5290 may be disposed at the second bonding interface 5002 and may be electrically connected to the memory cell array through the fourth interconnection structure 5280.

The first bonding pad 5150 may be electrically connected to the third bonding pad 5260 at the first bonding interface 5001, and the memory cell array may be electrically connected to the first peripheral circuit through the first bonding pad 5150 and the third bonding pad 5260. The second bonding pad 5151 may be electrically connected to the fourth bonding pad 5290 at the second bonding interface 5002, and the memory cell array may be electrically connected to the second peripheral circuit through the second bonding pad 5151 and the fourth bonding pad 5290.

The first contact plug 5295 may extend through the second interlayer insulating layer 5240 or a dummy stack, and the second contact plug 5297 may extend through the third substrate 5201. The first contact plug 5295 may be connected to the second contact plug 5297, and the first peripheral circuit may be connected to the second peripheral circuit through the first bonding pad 5150, the third bonding pad 5260, the first contact plug 5295, the second contact plug 5297, the fourth bonding pad 5290, and the second bonding pad 5151.

The semiconductor device may be manufactured using a method such as hybrid bonding, metal bonding, insulator bonding, or semiconductor bonding. The semiconductor device may be manufactured by manufacturing a first wafer including the first peripheral circuit, a second wafer including the second peripheral circuit, and a third wafer including the memory cell array, and bonding the first to third wafers together. For example, the third wafer may be flipped and bonded to the first wafer, and a substrate of the third wafer may be removed to form the source structure 5230. The second wafer may be flipped and bonded to the third wafer.

FIG. 15B is a diagram illustrating the structure of a semiconductor device in accordance with an embodiment.

Referring to FIG. 15B, the semiconductor device may include a first semiconductor structure 5300, a second semiconductor structure 5400A, and a third semiconductor structure 5400B. Bonding interfaces 5003 and 5004 may be located in the semiconductor device, and the first semiconductor structure 5300, the second semiconductor structure 5400A, and the third semiconductor structure 5400B may be distinguished by the bonding interfaces 5003 and 5004. The second semiconductor structure 5400A may be disposed between the first semiconductor structure 5300 and the third semiconductor structure 5400B. The first semiconductor structure 5300 may include a peripheral circuit, the second semiconductor structure 5400A may include a first memory cell array, and the third semiconductor structure 5400B may include a second memory cell array.

The first semiconductor structure 5300 may include a substrate 5310, a transistor 5320, a first interlayer insulating layer 5330, a first interconnection structure 5340, and a first bonding pad 5350. The transistor 5320 may be included in the peripheral circuit. The peripheral circuit may include a row decoder, a page buffer, an input/output circuit, a logic circuit, and the like. The first interconnection structure 5340 may be disposed in the first interlayer insulating layer 5330 and may include a via, a wiring line, and the like. The first bonding pad 5350 may be disposed at a first bonding interface 5003 and may be electrically connected to the peripheral circuit through the first interconnection structure 5340.

The second semiconductor structure 5400A may include a first gate structure 5410, a first channel structure 5420, a first source structure 5430, a second interlayer insulating layer 5440, a second interconnection structure 5450, a second bonding pad 5460, a third interlayer insulating layer 5470, a third interconnection structure 5480, and a third bonding pad 5490. The first gate structure 5410 may include first gate lines 5411 alternately stacked with first insulating layers 5412. The first source structure 5430 may be disposed over or under the first gate structure 5410. The first channel structure 5420 may include a first channel layer 5421, a first memory layer 5422, and/or a first insulating core 5423. The first channel layer 5421 may extend through the first gate structure 5410 and may be connected to the first source structure 5430. The second interconnection structure 5450 may be disposed in the second interlayer insulating layer 5440 and may include a via, a wiring line, and the like. For example, the second interconnection structure 5450 may include a bit line 5452. The third interconnection structure 5480 may be disposed in the third interlayer insulating layer 5470 and may include a via, a wiring line, and the like. The second bonding pad 5460 may be disposed at the first bonding interface 5003 and may be electrically connected to the first memory cell array through the second interconnection structure 5450. The third bonding pad 5490 may be disposed at a second bonding interface 5004, and may be electrically connected to the first memory cell array through the third interconnection structure 5480.

The third semiconductor structure 5400B may include a second gate structure 5416, a second channel structure 5426, a second source structure 5431, a fourth interlayer insulating layer 5441, a fourth interconnection structure 5451, and a fourth bonding pad 5461. The second gate structure 5416 may include second gate lines 5417 alternately stacked with second insulating layer 5418. The second source structure 5431 may be disposed over or under the second gate structure 5416. The second source structure 5431 may be electrically isolated from the first source structure 5430 and driven separately from the first source structure 5430 or may be electrically connected to the first source structure 5430 and driven in common with the first source structure 5430. The second channel structure 5426 may include a second channel layer 5427, a second memory layer 5428, and/or a second insulating core 5429. The second channel layer 5427 may extend through the second gate structure 5416 and may be connected to the second source structure 5431. The fourth interconnection structure 5451 may be disposed in the fourth interlayer insulating layer 5441 and may include a via, a wiring line, and the like. For example, the fourth interconnection structure 5451 may include a bit line 5453. The fourth bonding pad 5461 may be disposed at the second bonding interface 5004 and may be electrically connected to the second memory cell array through the fourth interconnection structure 5451.

The first bonding pad 5350 may be electrically connected to the second bonding pad 5460 at the first bonding interface 5003, and the first memory cell array may be electrically connected to the peripheral circuit through the first bonding pad 5350 and the second bonding pad 5460. The third bonding pad 5490 may be electrically connected to the fourth bonding pad 5461 at the second bonding interface 5004, and the second memory cell array may be electrically connected to the first memory cell array through the third bonding pad 5490 and the fourth bonding pad 5461.

The semiconductor device may be manufactured using a method such as hybrid bonding, metal bonding, insulator bonding, or semiconductor bonding. The semiconductor device may be manufactured by manufacturing a first wafer including the peripheral circuit, a second wafer including the first memory cell array, and a third wafer including the second memory cell array, and bonding the first to third wafers together. For example, the second wafer may be flipped and bonded to the first wafer, and a substrate of the second wafer may be removed to form the first source structure 5430. The third wafer may be flipped and bonded to the second wafer, and a substrate of the third wafer may be removed to form the second source structure 5431.

FIG. 15C is a diagram illustrating the structure of a semiconductor device in accordance with an embodiment.

Referring to FIG. 15C, the semiconductor device may include a first semiconductor structure 5500, a second semiconductor structure 5600A, and a third semiconductor structure 5600B. Bonding interfaces 5005 and 5006 may be located in the semiconductor device, and the first semiconductor structure 5500, the second semiconductor structure 5600A, and the third semiconductor structure 5600B may be distinguished by the bonding interfaces 5005 and 5006. The second semiconductor structure 5600A may be disposed between the first semiconductor structure 5500 and the third semiconductor structure 5600B. The first semiconductor structure 5500 may include a peripheral circuit, the second semiconductor structure 5600A may include a first memory cell array, and the third semiconductor structure 5600B may include a second memory cell array.

The first semiconductor structure 5500 may include a substrate 5510, a transistor 5520, a first interlayer insulating layer 5530, a first interconnection structure 5540, and a first bonding pad 5550. The transistor 5520 may be included in the peripheral circuit. The peripheral circuit may include a row decoder, a page buffer, an input/output circuit, a logic circuit, and the like. The first interconnection structure 5540 may be disposed in the first interlayer insulating layer 5530 and may include a via, a wiring line, and the like. The first bonding pad 5550 may be disposed at a first bonding interface 5005 and may be electrically connected to the peripheral circuit through the first interconnection structure 5540.

The second semiconductor structure 5600A may include a first gate structure 5610, a first channel structure 5620, a first source structure 5630, a second interlayer insulating layer 5640, a second interconnection structure 5650, a second bonding pad 5660, a third interlayer insulating layer 5670, a third interconnection structure 5680, and a third bonding pad 5690. The first gate structure 5610 may include first gate lines 5611 alternately stacked with first insulating layers 5612. The first source structure 5630 may be disposed over or under the first gate structure 5610. The first channel structure 5620 may include a first channel layer 5621, a first memory layer 5622, and/or a first insulating core 5623. The first channel layer 5621 may extend through the first gate structure 5610 and may be connected to the first source structure 5630. The second interconnection structure 5650 may be disposed in the second interlayer insulating layer 5640 and may include a via, a wiring line, and the like. For example, the second interconnection structure 5650 may include a bit line 5652. The third interconnection structure 5680 may be disposed in the third interlayer insulating layer 5670 and may include a via, a wiring line, and the like. The second bonding pad 5660 may be disposed at a second bonding interface 5006 and may be electrically connected to the first memory cell array through the second interconnection structure 5650. The third bonding pad 5690 may be disposed at the first bonding interface 5005 and may be electrically connected to the first memory cell array through the third interconnection structure 5680.

The third semiconductor structure 5600B may include a second gate structure 5616, a second channel structure 5626, a second source structure 5631, a fourth interlayer insulating layer 5641, a fourth interconnection structure 5651, and a fourth bonding pad 5661. The second gate structure 5616 may include second gate lines 5617 alternately stacked with second insulating layer 5618. The second source structure 5631 may be disposed over or under the second gate structure 5616. The second source structure 5631 may be electrically isolated from the first source structure 5630 and driven separately from the first source structure 5630 or may be electrically connected to the first source structure 5630 and driven in common with the first source structure 5630. The second channel structure 5626 may include a second channel layer 5627, a second memory layer 5628, and/or a second insulating core 5629. The second channel layer 5627 may extend through the second gate structure 5616 and may be connected to the second source structure 5631. The fourth interconnection structure 5651 may be disposed in the fourth interlayer insulating layer 5641 and may include a via, a wiring line, and the like. For example, the fourth interconnection structure 5651 may include a bit line 5653. The fourth bonding pad 5661 may be disposed at the second bonding interface 5006 and may be electrically connected to the second memory cell array through the fourth interconnection structure 5651.

The first bonding pad 5550 may be electrically connected to the third bonding pad 5690 at the first bonding interface 5005, and the first memory cell array may be electrically connected to the peripheral circuit through the first bonding pad 5550 and the third bonding pad 5690. The second bonding pad 5660 may be electrically connected to the fourth bonding pad 5661 at the second bonding interface 5006, and the second memory cell array may be electrically connected to the first memory cell array through the second bonding pad 5660 and the fourth bonding pad 5661.

The semiconductor device may be manufactured using a method such as hybrid bonding, metal bonding, insulator bonding, or semiconductor bonding. The semiconductor device may be manufactured by manufacturing a first wafer including the peripheral circuit, a second wafer including the first memory cell array, and a third wafer including the second memory cell array, and bonding the first to third wafers together. For example, the second wafer may be flipped and bonded to the third wafer, and a substrate of the second wafer may be removed to form the first source structure 5630. The second wafer and the first wafer may be bonded, and a substrate of the third wafer may be removed to form the second source structure 5631.

FIG. 15D is a diagram illustrating the structure of a semiconductor device in accordance with an embodiment.

Referring to FIG. 15D, the semiconductor device may include a first semiconductor structure 5700A, a second semiconductor structure 5700B, a third semiconductor structure 5800A, and a fourth semiconductor structure 5800B. Bonding interfaces 5007, 5008, and 5009 may be located in the semiconductor device, and the first semiconductor structure 5700A, the second semiconductor structure 5700B, the third semiconductor structure 5800A, and the fourth semiconductor structure 5800B may be distinguished by the bonding interfaces 5007, 5008, and 5009. The third semiconductor structure 5800A and the fourth semiconductor structure 5800B may be disposed between the first semiconductor structure 5700A and the second semiconductor structure 5700B. The first semiconductor structure 5700A may include a first peripheral circuit, the second semiconductor structure 5700B may include a second peripheral circuit, the third semiconductor structure 5800A may include a first memory cell array, and the fourth semiconductor structure 5800B may include a second memory cell array.

The first semiconductor structure 5700A may include a first substrate 5710, a first transistor 5720, a first interlayer insulating layer 5730, a first interconnection structure 5740, and a first bonding pad 5750. The first transistor 5720 may be included in the first peripheral circuit. The first peripheral circuit may include a row decoder, a page buffer, an input/output circuit, a logic circuit, and the like. The first interconnection structure 5740 may be disposed in the first interlayer insulating layer 5730 and may include a via, a wiring line, and the like. The first bonding pad 5750 may be disposed at a first bonding interface 5007 and may be electrically connected to the first peripheral circuit through the first interconnection structure 5740.

The second semiconductor structure 5700B may include a second substrate 5711, a second transistor 5721, a second interlayer insulating layer 5731, a second interconnection structure 5741, and a second bonding pad 5751. The second transistor 5721 may be included in the second peripheral circuit. The second peripheral circuit may include a row decoder, a page buffer, an input/output circuit, a logic circuit, and the like. The second interconnection structure 5741 may be disposed in the second interlayer insulating layer 5731 and may include a via, a wiring line, and the like. The second bonding pad 5751 may be disposed at a second bonding interface 5008 and may be electrically connected to the second peripheral circuit through the second interconnection structure 5741.

The third semiconductor structure 5800A may include a first gate structure 5810, a first channel structure 5820, a first source structure 5830, a third interlayer insulating layer 5840, a third interconnection structure 5850, a third bonding pad 5860, and a first contact plug 5870. The first gate structure 5810 may include first gate lines 5811 alternately stacked with first insulating layers 5812. The first source structure 5830 may be disposed over or under the first gate structure 5810. The first channel structure 5820 may include a first channel layer 5821, a first memory layer 5822, and/or a first insulating core 5823. The first channel layer 5821 may extend through the first gate structure 5810 and may be connected to the first source structure 5830. The third interconnection structure 5850 may be disposed in the third interlayer insulating layer 5840 and may include a via, a wiring line, and the like. For example, the third interconnection structure 5850 may include a bit line 5852. The third bonding pad 5860 may be disposed at the first bonding interface 5007 and may be electrically connected to the first memory cell array through the third interconnection structure 5850.

The fourth semiconductor structure 5800B may include a second gate structure 5816, a second channel structure 5826, a second source structure 5831, a fourth interlayer insulating layer 5841, a fourth interconnection structure 5851, a fourth bonding pad 5861, and a second contact plug 5880. The second gate structure 5816 may include second gate lines 5817 alternately stacked with second insulating layer 5818. The second source structure 5831 may be disposed over or under the second gate structure 5816. The second source structure 5831 may be electrically connected to the first source structure 5830 and driven in common with the first source structure 5830. The second channel structure 5826 may include a second channel layer 5827, a second memory layer 5828, and/or a second insulating core 5829. The second channel layer 5827 may extend through the second gate structure 5816 and may be connected to the second source structure 5831. The fourth interconnection structure 5851 may be disposed in the fourth interlayer insulating layer 5841 and may include a via, a wiring line, and the like. For example, the fourth interconnection structure 5851 may include a bit line 5853. The fourth bonding pad 5861 may be disposed at the second bonding interface 5008 and may be electrically connected to the second memory cell array through the fourth interconnection structure 5851.

The first bonding pad 5750 may be electrically connected to the third bonding pad 5860 at the first bonding interface 5007, and the first memory cell array may be electrically connected to the first peripheral circuit through the first bonding pad 5750 and the third bonding pad 5860. The second bonding pad 5751 may be electrically connected to the fourth bonding pad 5861 at the second bonding interface 5008, and the second memory cell array may be electrically connected to the second peripheral circuit through the second bonding pad 5751 and the fourth bonding pad 5861. The first source structure 5830 may be bonded to the second source structure 5831 at a third bonding interface 5009. Thus, the first memory cell array may be electrically connected to the second memory cell array.

The first contact plug 5870 may extend through the third interlayer insulating layer 5840 or a dummy stack, and the second contact plug 5880 may extend through the fourth interlayer insulating layer 5841 or a dummy stack. The first contact plug 5870 may be connected to the second contact plug 5880, and the first peripheral circuit may be connected to the second peripheral circuit through the first bonding pad 5750, the third bonding pad 5860, the first contact plug 5870, the second contact plug 5880, the fourth bonding pad 5861, and the second bonding pad 5751.

The semiconductor device may be manufactured using a method such as hybrid bonding, metal bonding, insulator bonding, or semiconductor bonding. The semiconductor device may be manufactured by manufacturing a first wafer including the first peripheral circuit, a second wafer including the first memory cell array, a third wafer including the second peripheral circuit, and a fourth wafer including the second memory cell array, and bonding the first to fourth wafers together. For example, the second wafer may be flipped and bonded to the first wafer, and a substrate of the second wafer may be removed to form the first source structure 5830. The fourth wafer may be flipped and bonded to the third wafer, and a substrate of the fourth wafer may be removed to form the second source structure 5831. The second wafer may be bonded to the fourth wafer.

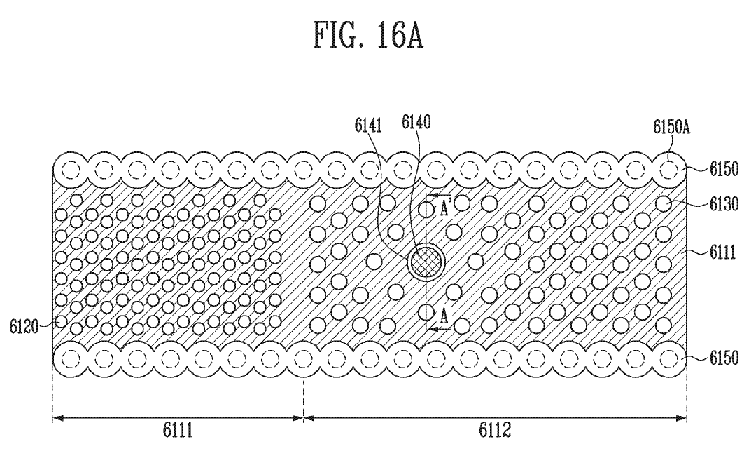

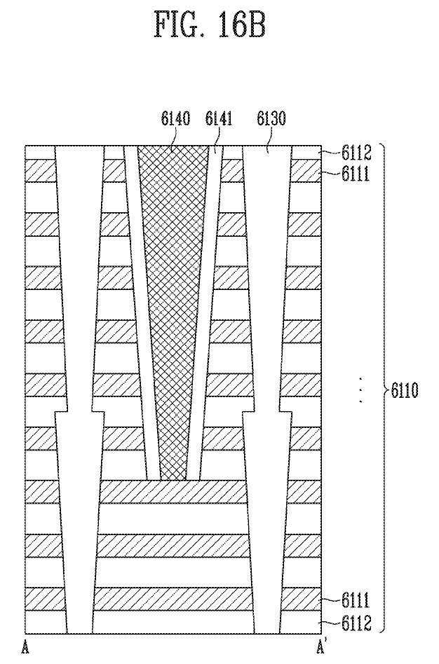

FIGS. 16A and 16B are diagrams illustrating the structure of a semiconductor device in accordance with an embodiment. FIG. 16B is a cross-sectional view taken along line A-A’ of FIG. 16A.

Referring to FIGS. 16A and 16B, the semiconductor device may include a gate structure 6110, channel structures 6120 (e.g., the channel structure 13, 14, 15, and 16 of FIG. 1A), supports 6130, a contact plug 6140, an insulating spacer 6141, and slit structures 6150. The term “slit structure” in the present disclosure does not indicate that a slit has a structure but rather is so named because the process of forming a slit structure utilizes a slit. The slit structures 6150 may extend in one direction, and the gate structure 6110 may be disposed between the slit structures 6150. Each of the slit structures 6150 may include an insulating material, a semiconductor material, and/or a conductive material. The gate structure 6110 may include gate lines 6111 alternately stacked with insulating layers 6112. The gate lines may be word lines, a source select line, or a drain select line.

The gate structure 6110 may include a cell region 6111 and a contact region 6112. The channel structures 6120 may be disposed in the cell region 6111 of the gate structure 6110. The channel structures 6120 may extend in a vertical direction through the gate structure 6110, and memory cells may be stacked along the channel structures 6120. The supports 6130 and the contact plug 6140 may be disposed in the contact region 6112 of the gate structure 6110. The supports 6130 may extend in the vertical direction through the gate structure 6110. Each of the supports 6130 may include an insulating material, a semiconductor material, and/or a conductive material.

The contact plug 6140 may be electrically connected to a gate line 6111. For example, the contact region 6112 of the gate structure 6110 may include a staircase structure (not shown), and the contact plug 6140 may be electrically connected to the gate line through the staircase structure. For example, the gate structure 6110 may not include the staircase structure, and the contact plug 6140 may extend through the gate structure 6110 and be electrically connected to the gate line. The insulating spacer 6141 may surround a sidewall of the contact plug 6140.

Processes of manufacturing the channel structures 6120, the supports 6130, and the slit structures 6150 may be performed simultaneously. Holes that form the channel structures 6120, the supports 6130, and the slit structures 6150 may be simultaneously formed, and sacrificial layers may be formed in the holes. The sacrificial layers are removed to form holes, and structures are formed within the holes. For example, holes 6150A arranged in a row may be formed in a region where the slit structure is to be formed. A slit may be formed by expanding the holes 6150A thereby connecting the holes 6150A together, and the slit structure 6150 may be formed in the slit. In such an example, the sidewalls of the slit structure 6150 may include irregularities or uneven surfaces.

The semiconductor device may be manufactured using a replacement process. For example, a stack may be formed including sacrificial layers alternately stacked with insulating layers, and a contact hole may be formed extending through the stack. A sacrificial pattern may be formed in the contact hole, and the sacrificial layers may be replaced with the gate lines 6111 to form the gate structure 6110. The sacrificial pattern may be removed, and the insulating spacer 6141 may be formed on sidewalls of the stack exposed by the contact hole. The contact plug 6140 may be formed within the insulating spacer 6141 formed in the contact hole.

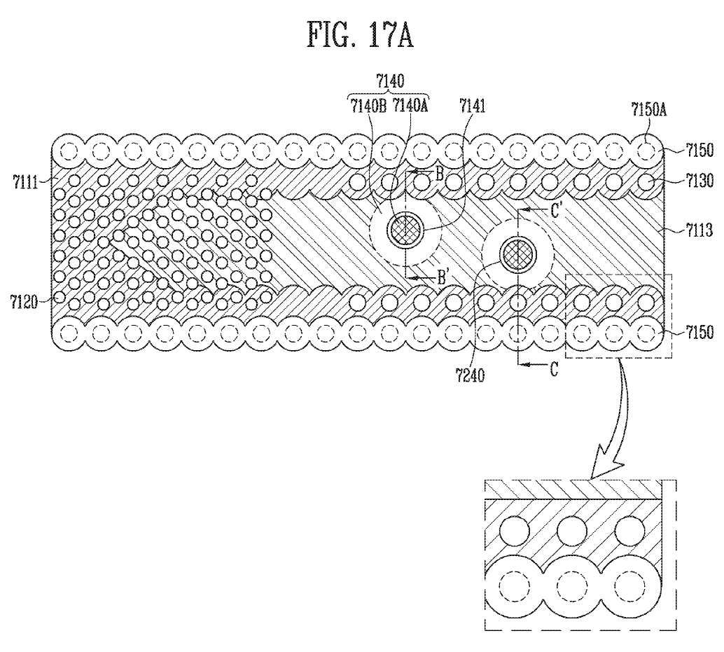

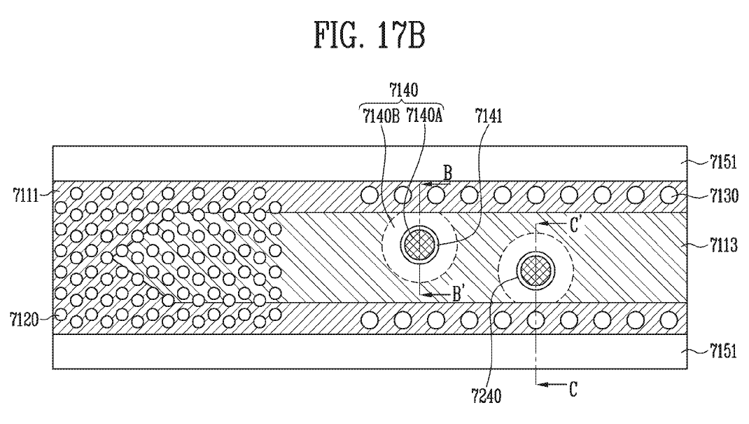

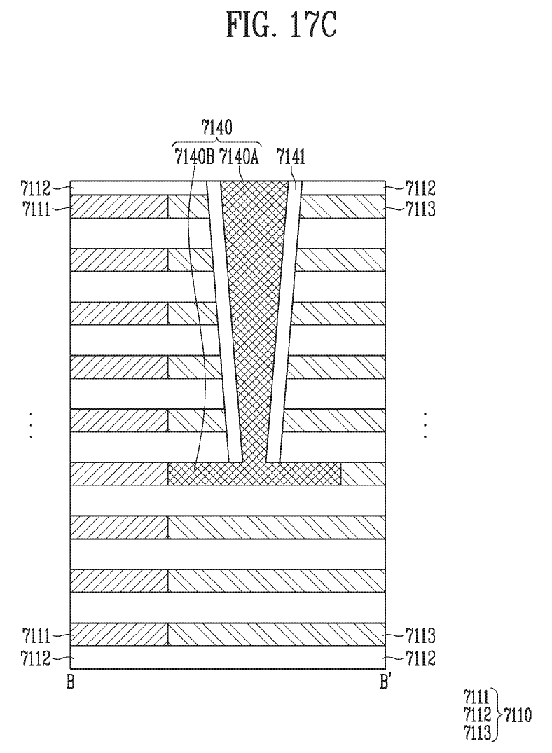

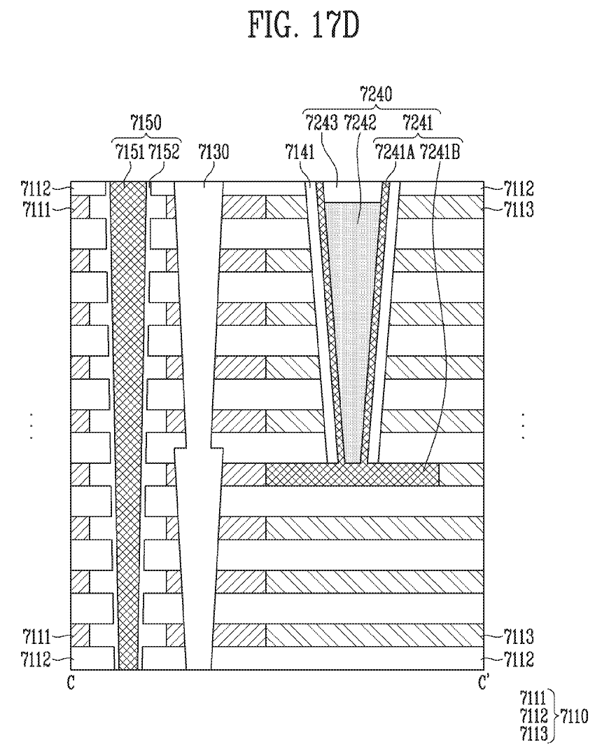

FIGS. 17A to 17D are a diagram illustrating the structure of a semiconductor device in accordance with an embodiment. FIG. 17C is a cross-sectional view taken along line B-B’ of FIG. 17A. FIG. 17D is a modified example of FIG. 17C and is a cross-sectional view taken along line C-C’ of FIG. 17A.

Referring to FIGS. 17A and 17B, the semiconductor device may include a gate structure 7110, channel structures 7120 (e.g., the channel structure 13, 14, 15, and 16 of FIG. 1A), supports 7130, a contact plug 7140, an insulating spacer 7141, and slit structures 7150 and 7151.

The slit structures 7150 may extend in one direction, and the gate structure 7110 may be disposed between the slit structures 7150. Referring to FIG. 17A, the slit structures 7150 may be formed within a slit defined by extending and connecting holes 7150A arranged in a row, and may have irregularities on their sidewalls. Referring to FIG. 17B, the slit structure 7151 may be formed within a line-shaped slit, and the sidewalls may have a linear shape without irregularities. Each of the slit structures 7150 and 7151 may include an insulating material, a semiconductor material, and/or a conductive material.

The gate structure 7110 may include gate lines 7111, insulating layers 7112, and dielectric layers 7113. The gate lines 7111 are alternately stacked with the insulating layers 7112, and the insulating layers 7112 may extend between the stacked dielectric layers 7113. The gate line 7111 may surround the dielectric layer 7113. The interface between the gate line 7111 and the dielectric layer 7113 may be uneven or corrugated, or may have a linear shape. The supports 7130 may be disposed between the dielectric layers 7113 and the slit structures 7150, and may extend through the gate lines 7111 and the insulating layers 7112.

The contact plug 7140 may include a pillar portion 7140A and a contact portion 7140B protruding from the pillar portion 7140A. The pillar portion 7140A and the contact portion 7140B may be formed as a single layer or may be formed as separate layers. The pillar portion 7140A may extend in the vertical direction through the insulating layers 7112 and the dielectric layers 7113. The contact portion 7140B may be disposed at a level corresponding to a dielectric layer 7113 and may extend in a horizontal direction to be electrically connected to the gate line 7111. The insulating spacer 7141 may surround the pillar portion 7140A. The semiconductor device may include a plurality of contact plugs 7140, and each of the plurality of contact plugs 7140 may extend to a different depth and be connected to a different gate line 7111. In an embodiment, the pillar 7120A and the contact 7120B are formed as a single unified structure, for example, formed in one process using the same material. Alternatively, the pillar 7120A and the contact 7120B may be formed separately and connected together.

Referring to FIGS. 17A and 17D, the semiconductor device may include a gate structure 7110, channel structures 7120, a contact plug 7240, an insulating spacer 7141, supports 7130, and a slit structure 7150. The gate structure 7110 may include gate lines 7111, insulating layers 7112, and dielectric layers 7113. The gate lines 7111 are alternately stacked with the insulating layers 7112, and the insulating layers 7112 may extend between the stacked dielectric layers 7113.

The supports 7130 may extend through the gate lines 7111 that are alternately stacked with the insulating layers 7112. The supports 7130 may each include an insulating material, a semiconductor material, and/or a conductive material. The slit structure 7150 may include a structure formed in a slit used as a passage for a replacement process and may extend between adjacent gate structures 7110. For example, the slit structure 7150 may include a conductive layer 7151 and an insulating spacer 7152 surrounding sidewalls of the conductive layer 7151. The insulating spacer 7152 may include protrusions protruding toward the gate lines 7111.

The contact plug 7240 may include a barrier layer 7241, a gap-fill insulating layer 7242, and a contact pad 7243. The gap-fill insulating layer 7242 may extend in the vertical direction through the dielectric layers 7113 and the insulating layers 7112. The contact pad 7243 may be disposed over the gap-fill insulating layer 7242 and may include metal such as tungsten. The barrier layer 7241 may include a pillar portion 7241A and a contact portion 7241B. The pillar portion 7241A may surround sidewalls of the gap-fill insulating layer 7242 and the contact pad 7243. The contact portion 7241B may be disposed below a lower surface of the gap-fill insulating layer 7242 and may extend in the horizontal direction to electrically connect to the gate line 7111. The insulating spacer 7141 may surround the pillar portion 7241A. The semiconductor device may include a plurality of contact plugs 7240, and each of the plurality of contact plugs 7240 may extend to a different depth and is connected to a different gate line 7111.

The semiconductor device may be manufactured using a replacement process. For example, the gate structure 7110 may be formed by forming a stack including sacrificial layers alternately stacked with the insulating layers 7112 and replacing the sacrificial layers with the gate lines 7111 through the slit. The stack may include a cell region and a contact region, and the sacrificial layers may remain in a region of the contact region spaced apart from the slit. The dielectric layers 7113 of the gate structure 7110 may be the remaining sacrificial layers. A contact hole extending through the insulating layers 7112 and the dielectric layers 7113 may be formed, and the insulating spacer 7141 may be formed on sidewalls of the stack exposed by the contact hole. By etching the dielectric layer 7113 exposed at a lower end of the insulating spacer 7141 and the contact hole, a lower end of the contact hole may be expanded in the horizontal direction to expose the gate line 7111. The contact plug 7140 or the contact plug 7240 may be formed within the insulating spacer 7141 formed in the contact hole.

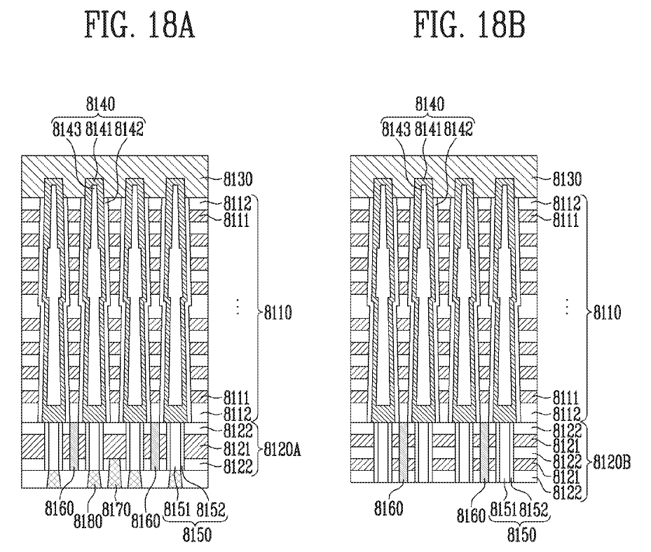

FIGS. 18A and 18B are diagrams illustrating the structure of a semiconductor device in accordance with an embodiment.

Referring to FIGS. 18A and 18B, the semiconductor device may include a first gate structure 8110, a second gate structure 8120A or 8120B, a source structure 8130, a first channel structure 8140, a second channel structure 8150, and an isolation insulating structure 8160. The first gate structure 8110 may include first gate lines 8111 alternately stacked with first insulating layers 8112. The first gate lines 8111 may be word lines or a source select line. The source structure 8130 may be disposed over the first gate structure 8110.

The second gate structure 8120A or 8120B may be disposed under the first gate structure 8110. Referring to FIG. 18A, the second gate structure 8120A may include a second gate line 8121 alternately stacked with second insulating layers 8122. The first contact plug 8170 may be connected to the second gate line 8121, and the second contact plugs 8180 may be connected to the second channel structures 8150. The first contact plug 8170 and the second contact plugs 8180 may be located in a cell region. Referring to FIG. 18B, the second gate structure 8120B may include second gate lines 8121 alternately stacked with second insulating layers 8122. Contact plugs may be connected to respective ones of the second gate lines 8121, and the contact plugs may be located in a contact region.

The second gate line 8121 may be a drain select line. The second gate line 8121 may be thicker than the first gate line 8111 or have substantially the same thickness as the first gate line 8111. The second gate line 8121 may include a different material from the first gate line 8111. For example, the first gate line 8111 may include metal such as tungsten (W) or molybdenum (Mo), and the second gate line 8121 may include polysilicon. Consecutive second gate lines 8121 disposed at the same level may be insulated by an isolation insulating structure 8160. In a plan view, the isolation insulating structures 8160 may extend in a line or a wave or zigzag shape.

The first channel structures 8140 may extend through the first gate structure 8110. The first channel structure 8140 may include a first channel layer 8141, a memory layer 8142, and/or an insulating core 8143. The second channel structures 8150 may extend through the second gate structure 8120A or 8120B and may be connected to the first channel structures 8140. The second channel structure 8150 may include a second channel layer 8151 and a gate insulating layer 8152.

The first gate structure 8110 and the second gate structure 8120A or 8120B may be formed by separate processes. For example, the first gate structure 8110 may be formed by forming a stack including sacrificial layers alternately stacked with the first insulating layers 8112 and replacing the sacrificial layers with the first gate lines 8111. The second gate structure 8120A or 8120B may be formed on the first gate structure 8110. At least one conductive layer and the second insulating layers 8122 may be formed, and the second gate lines 8121 and trenches between the second gate lines 8121 may be formed by etching at least one conductive layer and the second insulating layers 8122. The isolation insulating structures 8160 may be formed in the trenches.

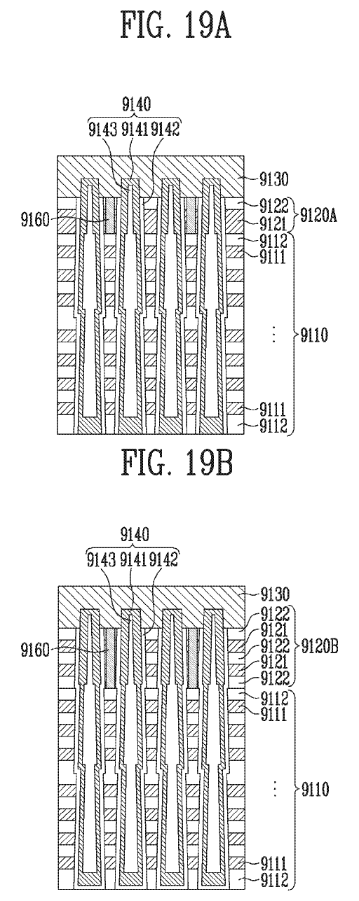

FIGS. 19A and 19B are diagrams illustrating the structure of a semiconductor device in accordance with an embodiment.

Referring to FIGS. 19A and 19B, a semiconductor device may include a first gate structure 9110, a second gate structure 9120A or 9120B, a source structure 9130, a channel structure 9140, and an isolation insulating structure 9160. The first gate structure 9110 may include first gate lines 9111 alternately stacked with first insulating layers 9112. The first gate lines 9111 may be word lines or a drain select line. The source structure 9130 may be disposed over the first gate structure 9110.

The second gate structure 9120A or 9120B may be disposed between the first gate structure 9110 and the source structure 9130. Referring to FIG. 19A, the second gate structure 9120A may include a second gate line 9121 alternately stacked with second insulating layers 9122. Referring to FIG. 19B, the second gate structure 9120B may include second gate lines 9121 alternately stacked with second insulating layers 9122. The second gate line 9121 may be a source select line. The second gate line 9121 may be thicker than the first gate line 9111 or have substantially the same thickness as the first gate line 9111. The second gate line 9121 may include a different material from the first gate line 9111. For example, the first gate line 9111 may include metal such as tungsten (W) or molybdenum (Mo), and the second gate line 9121 may include polysilicon. Consecutive second gate lines 9121 disposed at the same level may be insulated by an isolation insulating structure 9160. In a plan view, the isolation insulating structures 9160 may extend in a line or a wave or zigzag shape.

The channel structures 9140 may extend through the first gate structure 9110 and the second gate structure 9120A or 9120B. The channel structure 9140 may include a channel layer 9141, a memory layer 9142, and/or an insulating core 9143. Referring to FIGS. 1B, 19A, and 19B, the first region 14A of the channel layer 9141 may be disposed in the second gate structure 9120A or 9120B. The second and third regions 14B and 14C of the channel layer 9141 may be disposed in the first gate structure 9110. The thickness D1 of the first region 14A may be greater than the thickness D2 of the second region 14B.

The first gate structure 9110 and the second gate structure 9120A or 9120B may be formed by separate processes. For example, the second gate structure 9120A or 9120B may be formed on a substrate. At least one conductive layer and the second insulating layers 9122 may be formed, and the second gate lines 9121 and trenches between the second gate lines 9121 may be formed by etching at least one conductive layer and the second insulating layers 9122. The isolation insulating structures 9160 may be formed in the trenches. The first gate structure 9110 may be formed by forming a stack including sacrificial layers alternately stacked with the first insulating layers 9112 and replacing the sacrificial layers with the first gate lines 9111. A wafer bonding process may be performed, the substrate may be removed, and the source structure 9130 may be formed. In another example, the second gate structure 9120A or 9120B including at least one conductive layer and the second insulating layers 9122 may be formed on a substrate. The first gate structure 9110 may be formed by forming a stack including sacrificial layers alternately stacked with the first insulating layers 9112 and replacing the sacrificial layers with the first gate lines 9111. A wafer bonding process may be performed, and a rear surface of the second gate structure 9120A or 9120B may be exposed by removing the substrate. The second gate lines 9121 and trenches between the second gate lines 9121 may be formed by etching at least one conductive layer and the second insulating layers 9122, and the isolation insulating structures 9160 may be formed in the trenches. The source structure 9130 may be formed.

According to embodiments, a semiconductor device having a stabilized structure and improved reliability may be provided. In addition, a method of manufacturing a semiconductor device may be simplified with a lower level of difficulty of processes and lower manufacturing costs.

Embodiments have been disclosed herein, and although specific terms are employed, they are used and are to be interpreted in a generic and descriptive sense only and not for the purpose of limitation. Accordingly, it will be understood by a person of ordinary skill in the art to which the disclosure pertains that various changes in forms and details may be made without departing from the spirit and scope of the disclosure as set forth in the following claims.

What is claimed is:

1. A semiconductor device, comprising:
a stacked structure including conductive layers and insulating layers alternately stacked with each other in a first direction;
a source layer; and
a channel layer passing through the stacked structure and being in contact with the source layer,
wherein the channel layer includes a first region and a second region, and the first region is disposed between the source layer and the second region, and
wherein a first thickness of the first region is greater than a second thickness of the second region.

2. The semiconductor device of claim 1, wherein the conductive layers include a first conductive layers and a second conductive layers,
wherein the first conductive layers are disposed between the source layer and the second conductive layers, and
wherein the first region of the channel layer overlaps with the first conductive layers in a second direction crossing the first direction.

3. The semiconductor device of claim 2, wherein a thickness of one of the first conductive layers is the same as a thickness of one of the second conductive layers.

4. The semiconductor device of claim 2, wherein a thickness of one of the first conductive layers is greater than a thickness of one of the second conductive layers.

5. The semiconductor device of claim 2, further comprising an isolation insulating structure penetrating the first conductive layers.

6. The semiconductor device of claim 5, wherein the isolation insulating structure overlaps with the first conductive layers in a second direction crossing the first direction.

7. The semiconductor device of claim 1, wherein the first region of the channel layer is surrounded by the source layer.

8. The semiconductor device of claim 1, wherein the first region of the channel layer is in direct contact with the source layer.

9. The semiconductor device of claim 1, further comprising a memory layer disposed between the channel layer and the stacked structure.

10. The semiconductor device of claim 9, further comprising a memory pattern disposed between the channel layer and the source layer, and
wherein the memory layer is spaced apart from the memory pattern by the source layer.

11. The semiconductor device of claim 1, further comprising a peripheral circuit structure,
wherein the peripheral circuit structure is electrically connected to the channel layer.

12. The semiconductor device of claim 11, wherein the stacked structure is disposed between the source layer and the peripheral circuit structure.

13. The semiconductor device of claim 11, wherein the source layer is disposed between the stacked structure and the peripheral circuit structure.

14. The semiconductor device of claim 1, further comprising a bit line electrically connected to the channel layer,
wherein the second region of the channel layer is disposed between the first region and the bit line.

15. The semiconductor device of claim 1, wherein the first region and the second region of the channel layer are formed as an integral layer.
